(19) United States
(12) Patent Application Publication
(10) Pub. No.: US 2026/0136672 A1
(43) Pub. Date: May 14, 2026

(54) DISPLAY SUBSTRATE AND DISPLAY APPARATUS

(71) Applicants: Hefei Xinsheng Optoelectronics Technology Co., Ltd., Hefei, Anhui, (CN); BOE TECHNOLOGY GROUP CO., LTD., Beijing (CN); Beijing BOE Technology Development Co., Ltd., Beijing (CN)

(72) Inventors: Zhixiang ZOU, Beijing (CN); Liang LIN, Beijing (CN); Zhangtao WANG, Beijing (CN); Ran ZHANG, Beijing (CN); Zhonghao HUANG, Beijing (CN); Zhong XU, Beijing (CN); Chuan CHEN, Beijing (CN); Shuai YUAN, Beijing (CN)

(21) Appl. No.: 18/706,078

(22) PCT Filed: Aug. 11, 2023
(86) PCT No.: PCT/CN2023/112539

§ 371 Date: Apr. 30, 2024

(51) Int. Cl. H10D 86/40; H10D 86/01; H10D 86/60

(52) U.S. Cl. CPC H10D 86/443; H10D 86/0221; H10D 86/423; H10D 86/60

(57) ABSTRACT

A display substrate and a display apparatus are provided. The display substrate includes a base substrate, and gate lines and data lines cross with each other to define pixel units. Each pixel unit includes a first transistor and a second transistor, an active layer of the first transistor includes a first contact portion and a second contact portion, an active layer of the second transistor includes a third contact portion and a fourth contact portion, the first contact portion is electrically connected to the corresponding data line, the second contact portion is electrically connected to the third contact portion, and the fourth contact portion is electrically connected to the first electric pole. Along the second direction, a maximum distance between the first contact portion and the corresponding gate line is not less than a maximum distance between the fourth contact portion and the same gate line.

### TECHNICAL FIELD

The present disclosure relates to the field of display technology, and in particular to a display substrate and a display apparatus.

### BACKGROUND

A transistor is a core device in the display technology as a switching control element or an integrated element of a peripheral driving circuit. In the semiconductor field, the mobility refers to a speed of electrons moving in a semiconductor material. For a semiconductor display device, the mobility represents the display quality and lifetime achieved by the device of the same size.

However, with the optimized design for the semiconductor material of the device, problems such as a low threshold voltage, a negative shift under illumination and the like exist while the mobility is improved.

### SUMMARY

The present disclosure is directed to solving at least one of the technical problems in the related art and provides a display substrate and a display apparatus.

In a first aspect, the technical solution adopted for solving the technical problems in the related art is a display substrate, including a base substrate, and gate lines and data lines on the base substrate, and the gate lines and the data lines cross with each other to define a plurality of pixel units; the gate lines extend in a first direction, and the data lines extend in a second direction, and the first direction and the second direction intersect with each other; each pixel unit includes a first transistor and a second transistor, an active layer of the first transistor includes a first contact portion and a second contact portion, an active layer of the second transistor includes a third contact portion and a fourth contact portion, the first contact portion is electrically connected to the corresponding data line, the second contact portion is electrically connected to the third contact portion, and the fourth contact portion is electrically connected to a first electric pole of the pixel unit; and along the second direction, a maximum distance between the first contact portion and the corresponding gate line is not less than a maximum distance between the fourth contact portion and the same gate line.

In some embodiments, a width of the first contact portion is less than a width of the fourth contact portion along the first direction.

In some embodiments, an orthographic projection of the first contact portion on the base substrate overlaps with an orthographic projection of the corresponding data line on the base substrate, the first contact portion includes a first section and a second section connected to each other, the first section is electrically connected to the corresponding data line, and a width of the first section is greater than a width of the second section along the first direction.

In some embodiments, an orthographic projection of the fourth contact portion on the base substrate partially overlaps with an orthographic projection of the corresponding gate line on the base substrate, the fourth contact portion includes a third section and a fourth section connected to each other, the fourth section is electrically connected to the first electric pole, and a minimum width of the fourth section is greater than a minimum width of the third section along the second direction.

In some embodiments, the first contact portion is electrically connected to the corresponding data line through a first via, the fourth contact portion is electrically connected to the first electric pole through a second via, and a minimum distance between the first via and the corresponding gate line is greater than a minimum distance between the second via and the same gate line along the second direction.

In some embodiments, the first contact portion is electrically connected to the corresponding data line through the first via, and the fourth contact portion is electrically connected to the first electric pole through the second via and a third via, a minimum distance between the first via and the corresponding gate line is greater than a minimum distance between the second via and the same gate line along the second direction, and a minimum distance between the third via and the corresponding gate line is less than a minimum distance between the second via and the same gate line.

In some embodiments, each of the plurality of pixel units further includes an auxiliary component, the auxiliary component includes a fifth section and a sixth section connected to each other, the fifth section is electrically connected to the fourth contact portion through the second via, and the sixth portion is electrically connected to the first electric pole through the third via.

In some embodiments, the auxiliary components are in a same layer as the data lines, and the auxiliary components are between positions where every two adjacent data lines are connected to the first contact portions in the first direction.

In some embodiments, the first contact portion, the second contact portion, the third contact portion, and the fourth contact portion are in the same layer.

In some embodiments, the active layer of the first transistor and/or the active layer of the second transistor includes a metal oxide semiconductor material.

In some embodiments, the active layer of the first transistor and the active layer of the second transistor include a plurality of sub-layers arranged in a stack, and a sub-layer further from the base substrate has a lower mobility than a sub-layer closer to the base substrate.

In some embodiments, a gate electrode of the first transistor is on a side of the active layer of the first transistor away from the base substrate, a gate electrode of the second transistor is on a side of the active layer of the second transistor away from the base substrate, and the active layer of the first transistor and the active layer of the second transistor are in the same layer; and each data line is further used as a first electrode of the corresponding first transistor, the second contact portion is further used as a second electrode of the first transistor, the third contact portion is further used as a first electrode of the second transistor, and the second contact portion and the third contact portion are connected together to have a one-piece structure.

In some embodiments, the first electric pole is a pixel electrode, and an orthographic projection of the second contact portion and the third contact portion connected together to have a one-piece structure on the base substrate partially overlaps with an orthographic projection of at least one pixel electrode on the base substrate.

In some embodiments, for any two adjacent pixel units, an orthographic projection of the second contact portion and the third contact portion connected together to have a one-piece structure in one of the pixel units on the base substrate partially overlaps with an orthographic projection of the other pixel unit on the base substrate.

In some embodiments, the active layer of the first transistor further includes a first channel portion between the first contact portion and the second contact portion, the active layer of the second transistor further includes a second channel portion between the third contact portion and the fourth contact portion, and a shape of an outline of an orthographic projection of a pattern including the first channel portion, the second contact portion and the third contact portion connected together to have a one-piece structure, and the second channel portion on the base substrate has a U shape.

In some embodiments, a gate electrode of the first transistor and a gate electrode of the second transistor are in the same layer, the active layer of the first transistor and the active layer of the second transistor are in the same layer, and the first electrode and the second electrode of the first transistor are in the same layer as the first electrode and the second electrode of the second transistor; the gate electrode of the first transistor is on a side of the active layer away from the substrate, and the first electrode and the second electrode of the first transistor are on a side of the gate electrode away from the active layer; and each data line is further used as a first electrode of the corresponding first transistor, the second electrode of the first transistor and the first electrode of the second transistor are connected together to have a one-piece structure, the second electrode of the first transistor is electrically connected to the second contact portion through a fourth via, and the first electrode of the second transistor is electrically connected to the third contact portion through a fifth via.

In some embodiments, the display substrate further includes a light shielding layer on a side of the pixel units close to the base substrate; the active layer of the first transistor further includes a first channel portion between the first contact portion and the second contact portion, and the active layer of the second transistor further includes a second channel portion between the third contact portion and the fourth contact portion; and an orthographic projection of the light shielding layer on the base substrate at least covers an orthographic projection of each of the first channel portion and the second channel portion on the base substrate.

In some embodiments, an edge of an outline of an orthographic projection of the light shielding layer on the base substrate is spaced apart from an edge of an outline of an orthographic projection of the first channel portion on the base substrate by a first distance in the first direction, the edge of the outline of the orthographic projection of the light shielding layer on the base substrate is spaced apart from an edge of an outline of an orthographic projection of the second channel portion on the base substrate by a second distance in the first direction; and the first distance and/or the second distance is in a range from 4 μm to 6 μm.

In some embodiments, an edge of an outline of an orthographic projection of the light shielding layer on the base substrate is spaced apart from an edge of an outline of an orthographic projection of the first channel portion on the base substrate by a third distance in the second direction, the edge of the outline of the orthographic projection of the light shielding layer on the base substrate is spaced apart from an edge of an outline of an orthographic projection of the second channel portion on the base substrate by a fourth distance in the second direction, and the third distance and/or the fourth distance is in a range from 0 to 4 μm.

In some embodiments, the pixel units in a same row are electrically connected to a same gate line, and each gate line is further used as a gate electrode of the corresponding first transistor and a gate electrode of the corresponding second transistor.

In some embodiments, the display substrate further includes a gate insulating layer on a side of a gate electrode of the first transistor close to the active layer, and a thickness of the gate insulating layer is in a range from 10 nm to 30 nm.

In some embodiments, a gate electrode of the first transistor and a gate electrode of the second transistor are in the same layer, the active layer of the first transistor and the active layer of the second transistor are in the same layer, and the first electrode and the second electrode of the first transistor are in the same layer as the first electrode and the second electrode of the second transistor; the gate electrode of the first transistor is on a side of the active layer close to the base substrate, and the first electrode and the second electrode of the first transistor are on a side of the active layer away from the gate electrode; and each data line is further used as the first electrode of the corresponding first transistor, the second electrode of the first transistor and the first electrode of the second transistor are connected together to have a one-piece structure, and the second electrode of the first transistor is electrically connected to the second contact portion of the first transistor, the first electrode of the second transistor is electrically connected to the third contact portion of the second transistor.

In some embodiments, the pixel units in the same row are electrically connected to the same gate line, and each gate line serves as the gate electrode of the corresponding first transistor and the gate electrode of the corresponding second transistor; and each of the plurality of gate lines is of a composite-layer structure, which includes a buffer layer and a main conductive layer sequentially arranged on the base substrate.

In some embodiments, the display substrate further includes a gate insulating layer on a side of the gate electrode of the first transistor close to the active layer, and a thickness of the gate insulating layer is in a range from 30 nm to 50 nm.

In a second aspect, embodiments of the present disclosure further provide a display apparatus, including the display substrate of any one of the embodiments in the first aspect.

### BRIEF DESCRIPTION OF DRAWINGS

FIG. 1a is a schematic diagram of a structure of a pixel circuit according to an embodiment of the present disclosure;

FIG. 1b is a schematic diagram illustrating a positional relationship between a contact portion of an active layer and a gate line according to an embodiment of the present disclosure;

FIG. 2 is a schematic diagram illustrating a specific distribution of a first contact portion and a second contact portion according to an embodiment of the present disclosure;

FIG. 3a is a plan view illustrating an electrical connection between a transistor and a data line according to an embodiment of the present disclosure;

FIG. 3b is a plan view illustrating an electrical connection between a transistor and both of a data line and a first electric pole according to an embodiment of the present disclosure;

FIG. 4 is a schematic diagram of an active layer of a composite-layer structure according to an embodiment of the present disclosure;

FIG. 5a is a top plan view of a transistor with a top gate structure according to an embodiment of the present disclosure;

FIG. 5b is a cross-sectional view of the structure shown in FIG. 5a along a direction AA;

FIG. 6a is a schematic diagram of a plane where an active layer shown in FIG. 5b is located;

FIG. 6b is a schematic diagram of a plane where a first conductive layer shown in FIG. 5b is located;

FIG. 6c is a schematic diagram of a plane where first and second vias shown in FIG. 5b are located;

FIG. 6d is a schematic diagram of a plane where a second conductive layer shown in FIG. 5b is located;

FIG. 7 is a top plan view of a plurality of pixel units according to an embodiment of the present disclosure;

FIG. 8a is a schematic diagram of a plane where first sub-vias are located;

FIG. 8b is a schematic diagram of a plane where a second electric pole is located;

FIG. 8c is a schematic diagram of a plane where second sub-vias are located;

FIG. 8d is a schematic diagram of a plane where a first electric pole is located;

FIG. 9a is a schematic diagram of a structure of another transistor with a top gate structure according to an embodiment of the present disclosure;

FIG. 9b is a cross-sectional view of a structure shown in FIG. 9a along a direction BB;

FIG. 10 is a top view of a plane where a light shielding layer is located;

FIG. 11 is a top plan view of an exemplary light shielding layer according to an embodiment of the present disclosure;

FIG. 12a shows performance test results of a dual NMOS transistor device shown in FIG. 9b in a normal operating state (−1.5V);

FIG. 12b shows performance test results of a dual NMOS transistor device shown in FIG. 9b in a negative bias state (−8V);

FIG. 13a is a schematic diagram of a structure of a transistor with a bottom gate structure according to an embodiment of the present disclosure;

FIG. 13b is a cross-sectional view of a structure shown in FIG. 13a along a direction CC;

FIG. 14a is another schematic diagram of a structure of a transistor with a bottom gate structure according to an embodiment of the present disclosure;

FIG. 14b is a cross-sectional view of a structure shown in FIG. 14a along a direction DD;

FIGS. 15a to 15j are schematic diagrams illustrating a process for manufacturing a display substrate shown in FIG. 5b according to an embodiment of the present disclosure;

FIGS. 16a to 16j are schematic diagrams illustrating a process for manufacturing a display substrate shown in FIG. 9b according to an embodiment of the present disclosure;

FIGS. 17a to 17i are schematic diagrams illustrating a process for manufacturing a display substrate shown in FIG. 13b according to an embodiment of the present disclosure; and

FIGS. 18a to 18i are schematic diagrams illustrating a process for manufacturing a display substrate shown in FIG. 10 according to an embodiment of the present disclosure.

Reference numerals are: 1. a base substrate; 2. a pixel unit; 21. a pixel circuit; 22. a first electric pole; 23. a second electric pole; T1. a first transistor; T2. a second transistor; T11. a first electrode of the first transistor; T12. a second electrode of the first transistor; T13. an active layer of the first transistor; 13a. a first contact portion; 13b. a second contact portion; 13c. a first channel portion; T14. a gate electrode of the first transistor; T21. a first electrode of the second transistor; T22. a second electrode of the second transistor; T23. an active layer of the second transistor; 23a. a third contact portion; 23b. a fourth contact portion; 23c. a second channel portion; T24. a gate electrode of the second transistor; Gate. a gate line; Data. a data line; ACT. a semiconductor layer; ACT_1. a sub-layer; 31. a first insulating layer; 32. a second insulating layer; 33. a third insulating layer; 34. a fourth insulating layer; 35. a fifth insulating layer; 41. a first conductive layer; 42. a second conductive layer; 43. a third conductive layer; 50. a light shielding layer; X. a first direction; Y. a second direction; 6. an auxiliary component; 61. a fifth portion; 62. a sixth portion; Via1. a first via; Via2. a second via; Via3. a third via; Via31. a first sub-via; Via32. a second sub-via.

### DETAIL DESCRIPTION OF EMBODIMENTS

To make the objects, technical solutions and advantages of the embodiments of the present disclosure more apparent, the technical solutions of the embodiments of the present disclosure will be clearly and completely described below with reference to the drawings of the embodiments of the present disclosure. It is to be understood that the described embodiments are only a few, not all of, embodiments of the present disclosure. Components of the embodiments of the present disclosure, as generally described and illustrated in the drawings herein, could be arranged and designed in a various different configurations. Thus, the following detailed description of the embodiments of the present disclosure in the drawings is not intended to limit the protection scope of the present disclosure, but is merely representative of selected embodiments of the present disclosure. All other embodiments, which can be derived by a person skilled in the art from the embodiments of the present disclosure without any creative effort, are within the protection scope of the present disclosure.

Unless defined otherwise, technical or scientific terms used herein shall have the ordinary meaning as understood by one of ordinary skill in the art to which the present disclosure belongs. The terms “first”, “second” and the like used in the present disclosure are not intended to indicate any order, quantity, or importance, but rather are used for distinguishing one element from another. Further, the term “a”, “an”, “the” or the like used herein does not denote a limitation of quantity, but rather denotes the presence of at least one element. The term “comprising”, “including”, or the like means that the element or item preceding the term contains the element or item listed after the term and its equivalent, but does not exclude other elements or items. The term “connected”, “coupled” or the like is not limited to physical or mechanical connections, but may include electrical connections, whether direct or indirect connections. The terms “upper”, “lower”, “left”, “right” and the like are used only for indicating relative positional relationships, and when the absolute position of an object being described is changed, the relative positional relationships may also be changed accordingly.

In the related art, for amorphous silicon (a-Si), metal oxide (IGZO), and low-temperature polysilicon (LTPS) used in the industry, their effective mobilities actually are about 1 cm²/(V·s), 10 cm²/(V·s) and 80 cm²/(V·s), respectively. It can be seen that material properties of the low-temperature polysilicon (LTPS) are far ahead. In conventional technologies, the higher mobility in a range from about 20 cm²/(V·s) to 50 cm²/(V·s) can be achieved by developing different series of metal oxide materials to maintain the high mobility, such as an element ratio adjustment scheme of increasing indium (In) content, or an element change scheme of removing zinc (Zn) component or newly adding tin (Sn) component, or the like. However, while the mobility is improved, a series of problems are brought about as follows: on one hand, an optical band gap (Eg) of the material with the high mobility is smaller, and thus carriers are more easily generated, so that electrons in the material with the high mobility may absorb part of light in a visible light waveband and thus the electron transition occurs. Further, a device performance is represented as that a thin film transistor (TFT) is turned on in advance under illumination, defects are newly increased under illumination, negative bias temperature illumination stability (NBTIS) is seriously degraded, and the service life is seriously reduced. On the other hand, the development of the material with the high mobility is limited by the difficulty that the mobility and the optical band gap Eg cannot be improved at the same time, and the mass production of the material with the high mobility of Mob 30 or more has been slow in being achieved at present. In the related art, starting from a design direction for the TFT device and a dual-gate structure, the device performance with an ultra-high mobility of approximately 20 cm²/(V·s) or more can be achieved through a dual-gate TFT and an ultra-thin gate insulating layer (GI). However, while achieving the high mobility, such a device design reduces a current value at a low voltage, i.e., an off-state current (Ioff), thus resulting in a significant reduction in a threshold voltage (Vth) of the device. Meanwhile, a reduced thickness of the gate insulating layer GI may reduce a breakdown voltage of the device, and thus the failure risk of the device is increased. Therefore, there are problems of low threshold voltage, negative shift under illumination, and the like in manufacturing the device with the ultra-high mobility. With these problems, the ultra-high mobility of 50 cm²/(V·s) or more cannot be often achieved in the conventional technical solution, and the mass production does not actually exist in the market.

In view of the above, embodiments of the present disclosure provide a display substrate. Two transistors electrically connected to a first electric pole of a pixel unit are connected in series, so as to solve a leakage problem caused by a negative shift of a threshold voltage (Vth) of the device in the related art, improve a switching capability of the display substrate, and improve a service life of a product.

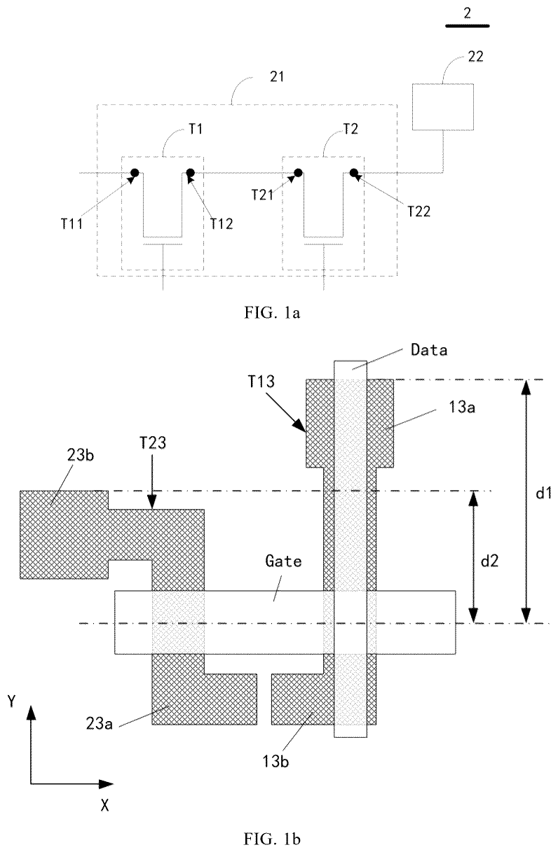

FIG. 1a is a schematic diagram of a structure of a pixel circuit according to an embodiment of the present disclosure; FIG. 1b is a schematic diagram illustrating a positional relationship between a contact portion of an active layer and a gate line according to an embodiment of the present disclosure. As shown in FIGS. 1a and 1b, the display substrate includes a base substrate 1 (not shown in FIGS. 1a and 1b, specifically, see FIG. 4), and gate lines Gate and data lines Data on the base substrate 1, the gate lines Gate and the data lines Data cross with each other to define a plurality of pixel units 2. The gate lines Gate extend in a first direction X, and the data lines Data extend in a second direction Y, and the first direction X and the second direction Y intersect with each other. For example, the first direction X and the second direction Y are perpendicular to each other. Each pixel unit 2 includes a pixel circuit 21 and a first electric pole 22, the pixel circuit 21 at least includes a first transistor T1 and a second transistor T2, an active layer T13 of the first transistor T1 includes a first contact portion 13a and a second contact portion 13b, an active layer T23 of the second transistor T2 includes a third contact portion 23a and a fourth contact portion 23b, the first contact portion 13a is electrically connected to the corresponding data line Data, the second contact portion 13b is electrically connected to the third contact portion 23a, and the fourth contact portion 23b is electrically connected to the first electric pole 22 of the pixel unit 2, and along the second direction Y, a maximum distance d1 between the first contact portion 13a and the corresponding gate line Gate is not less than a maximum distance d2 between the fourth contact portion 23b and the same gate line.

As shown in FIG. 1a, a second electrode T12 of the first transistor T1 is electrically connected to a first electrode T21 of the second transistor T2, and a second electrode T22 of the second transistor T2 is electrically connected to the first electric pole 22. The active layer T13 of the first transistor T1 and the active layer T23 of the second transistor T2 each are made of a metal oxide semiconductor material.

For example, the metal oxide semiconductor material may be one or more of indium gallium zinc oxide (IGZO), indium gallium tin oxide (IGTO), and indium tin zinc oxide (ITZO), indium gallium oxide (IGO), indium gallium zinc tin oxide (IGZTO), rare earth doped oxide (Ln-OS). The material may be in an amorphous, partially crystalline, single crystalline or polycrystalline state, and the active layer may be formed in a single-layer or multi-layer structure. According to the actual characteristics of the metal oxide semiconductor material, the metal oxide semiconductor material can improve the mobility of the transistor.

It should be noted that the transistor used in the embodiment of the present disclosure may be a field effect transistor (MOS transistor). A source electrode and a drain electrode of the MOS transistor are symmetrical, so that there is no difference between the source electrode and the drain electrode. In the embodiments of the present disclosure and the following description, to distinguish between the source electrode and the drain electrode of the transistor, one of the source electrode and the drain electrode is referred to as a first electrode, and the other one is referred to as a second electrode. In addition, the transistors may be classified into an N-type transistor and a P-type transistor according to their characteristics. Both the active layer T13 of the first transistor T1 and the active layer T23 of the second transistor T2 are made of the metal oxide semiconductor material in the embodiments of the present disclosure. It is to be understood that the transistors made of the metal oxide semiconductor material may only be formed as N-type transistors, and thus, the transistors in the embodiments of the present disclosure are N-type transistors. The first electrode of the transistor is the drain electrode of the N-type transistor, the second electrode of the transistor is the source electrode of the N-type transistor, and the source electrode and the drain electrode are conducted when a high-level signal is input into a gate electrode.

In practical applications of each pixel unit 2, not all transistors in the pixel unit 2 with the above structure can achieve similar effects. Therefore, it should be noted that for any one pixel unit 2, the second transistor T2 electrically connected to the first electric pole 22 is connected in series with the first transistor T1, a current value of one of the transistors is suppressed by the other transistor. In the extreme condition, when a negative bias of conductorization properties occurs in one of the transistors, the other transistor still remains in a normal operating state, so as to significantly reduce the off-state current and reduce the risk of the negative shift of the threshold voltage.

In the display substrate according to the embodiment of the present disclosure, the active layers of the dual transistors electrically connected to the first electric pole 22 are made of the metal oxide semiconductor material, so that the mobility of the transistors can be improved. The two transistors are connected in series with each other, and a current value of one of the transistors is suppressed by the other transistor. In the extreme condition, when a negative bias of conductorization properties occurs in one of the transistors, the other transistor still remains in a normal operating state, so as to significantly improve the threshold voltage of the whole device, thereby effectively solving the leakage problem of the whole device and the Mura problem of the display product caused by the leakage.

In some embodiments, as shown in FIG. 1b, a minimum width of the first contact portion 13a is less than a minimum width of the fourth contact portion 23b along the first direction X.

Here, the “width” may be understood as a maximum or average distance between boundaries of given layers along a given direction, and may be a lateral dimension or a longitudinal dimension.

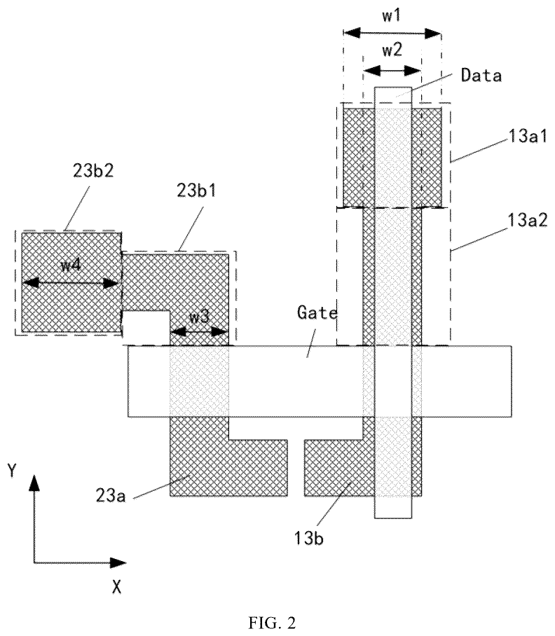

In some embodiments, FIG. 2 is a schematic diagram illustrating a specific distribution of a first contact portion and a second contact portion according to an embodiment of the present disclosure. As shown in FIG. 2, an orthographic projection of the first contact portion 13a on the base substrate 1 overlaps with an orthographic projection of the data line Data on the base substrate 1, the first contact portion 13a includes a first section 13a1 and a second section 13a2 connected to each other, the first section 13a1 is electrically connected to the data line Data, and a width w1 of the first section 13a1 is greater than a width w2 of the second section 13a2 along the first direction X.

In some embodiments, as shown in FIG. 2, an orthographic projection of the fourth contact portion 23b on the base substrate 1 partially overlaps with an orthographic projection of the gate line Gate on the base substrate 1, the fourth contact portion 23b includes a third section 23b 1 and a fourth section 23b2 connected to each other, the fourth connection 23b2 is electrically connected to the first electric pole 22, and a minimum width w4 of the fourth section 23b2 is greater than a minimum width w3 of the third section 23b1 along the second direction Y.

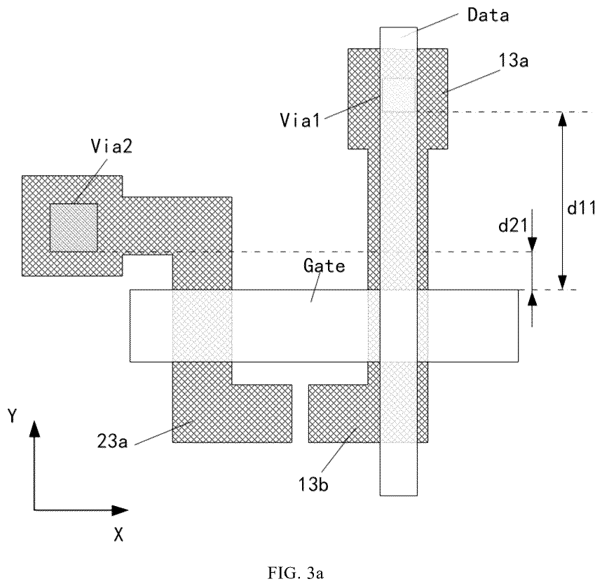

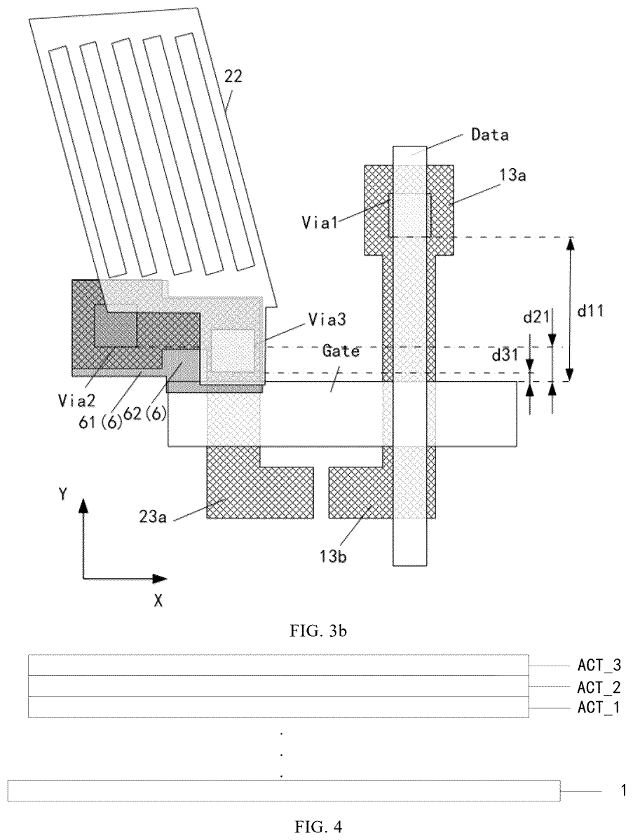

In some embodiments, FIG. 3a is a plan view illustrating an electrical connection between a transistor and a data line according to an embodiment of the present disclosure. As shown in FIG. 3a, the first contact portion 13a is electrically connected to the data line Data through a first via Via1, and the fourth contact portion 23b is electrically connected to the first electric pole 22 through a second via Via2. A minimum distance d11 between the first via Via1 and the gate line Gate is greater than a minimum distance d21 between the second via and the same gate line Gate along the second direction Y.

In some embodiments, FIG. 3b is a plan view illustrating an electrical connection between a transistor and both of a data line and a first electrode according to an embodiment of the present disclosure. As shown in FIG. 3b, the first contact portion 13a is electrically connected to the data line Data through the first via Via1, and the fourth contact portion 23b is electrically connected to the first electric pole 22 through the second via Via2 and a third via Via3. The minimum distance d11 between the first via Via1 and the gate line Gate is greater than the minimum distance d21 between the second via and the same gate line Gate along the second direction Y. A minimum distance d31 between the third via Via3 and the gate line Gate is less than the minimum distance d21 between the second via Via2 and the same gate line Gate.

In some embodiments, as shown in FIG. 3b, each pixel unit 2 further includes an auxiliary component 6, the auxiliary component 6 includes a fifth portion 61 and a sixth portion 62 connected to each other, the fifth portion 61 is electrically connected to the fourth contact portion 23b through the second via Via2, and the sixth portion 62 is electrically connected to the first electric pole 22 through the third via Via3.

In this embodiment, positions of the third via Via3 and the auxiliary component 6 are designed to reduce a via ratio, thereby increasing an aperture ratio, and increasing a lapping area of the first electric pole 22 (i.e., the pixel electrode ITO) and other layers and a yield of the product.

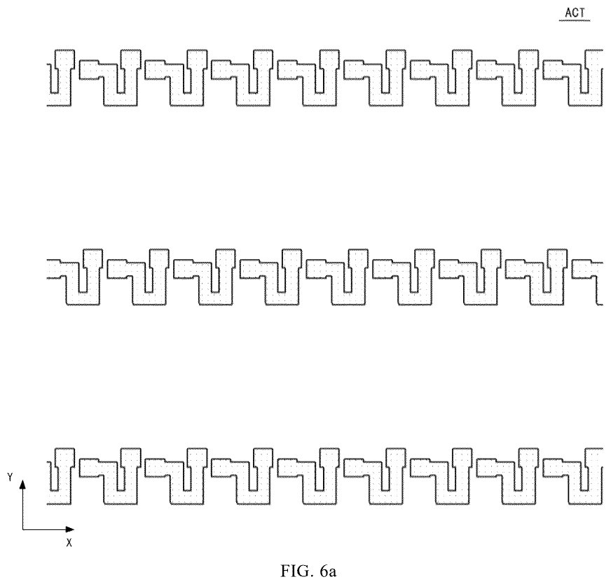

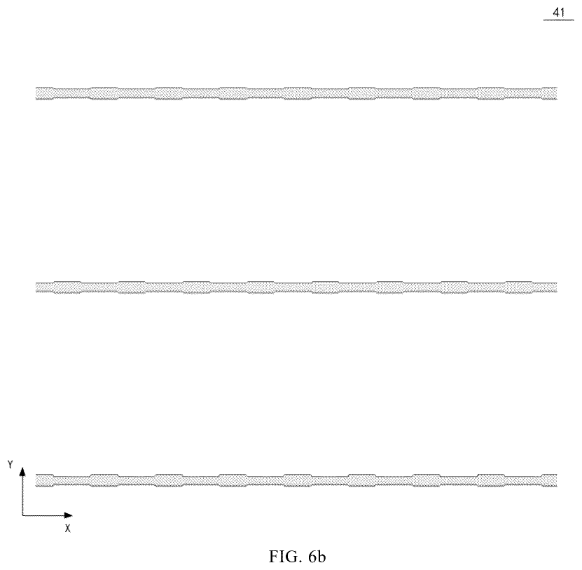

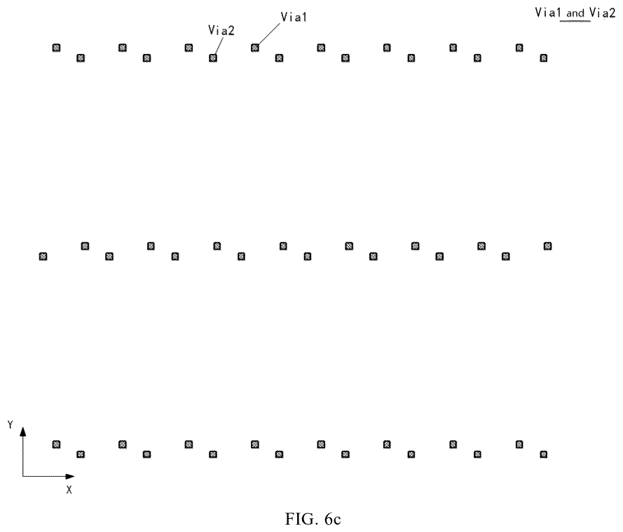

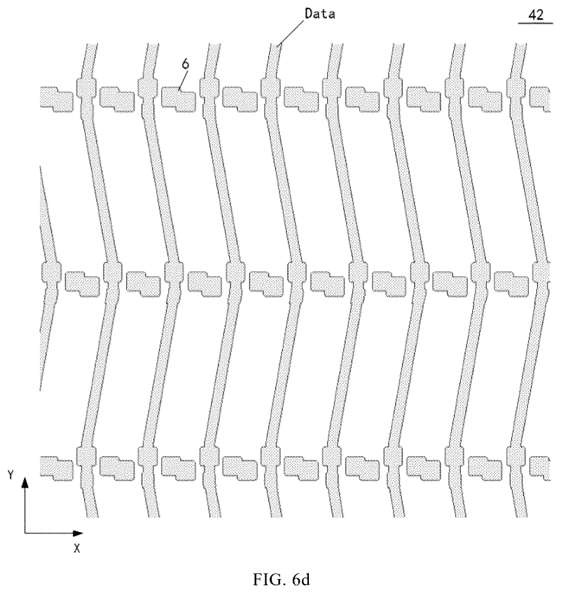

In some embodiments, as shown in FIG. 6d, the auxiliary components 6 are disposed in the same layer as the data lines Data, and the auxiliary components 6 are disposed between positions where every two adjacent data lines Data are connected to the first contact portions 13a in the first direction X.

In some embodiments, as shown in FIG. 6a, the first contact portion 13a, the second contact portion 13b, the third contact portion 23a, and the fourth contact portion 23b are disposed in the same layer.

In some embodiments, the active layer T13 of the first transistor T1 and/or the active layer T23 of the second transistor T2 include a plurality of sub-layers arranged in a stack, and a sub-layer further from the base substrate 1 has a lower mobility than a sub-layer closer to the base substrate 1.

FIG. 4 is a schematic diagram of an active layer of a composite-layer structure according to an embodiment of the present disclosure. As shown in FIG. 4, the active layer T13 of the first transistor T1 and/or the active layer T23 of the second transistor T2 include a plurality of sub-layers ACT_1, ACT_2 and ACT_3 arranged in a stack. A mobility of the sub-layer ACT_3 away from the base substrate 1 is lower than that of the sub-layer ACT_2 close to the base substrate 1, and the mobility of the sub-layer ACT_2 away from the base substrate 1 is lower than a mobility of the sub-layer ACT_1 close to the base substrate 1.

It should be noted that, the higher the mobility is, the lower the stability of the corresponding device is. Therefore, in the embodiment, by sequentially depositing the sub-layers with a less mobility, the stability of the device is improved while the device has higher mobility.

In some embodiments, when the active layer T13 of the first transistor T1 includes the plurality of sub-layers arranged in a stack, a material of the sub-layers includes one of IGO, ITZO, IGZTO. When the active layer T23 of the second transistor T2 includes the plurality of sub-layers arranged in a stack, a material of the sub-layers includes one of IGO, ITZO, IGZTO.

The metal oxide materials IGO, ITZO, and IGZTO are semiconductor materials having a mobility greater than or equal to 20 cm²/(V·s). Alternatively, the material of the sub-layers provided in the embodiments of the present disclosure is not limited to the above materials, and may include any other semiconductor material with a mobility greater than or equal to 20 cm²/(V·s), which is not listed in the embodiments of the present disclosure.

The process for forming the plurality of sub-layers arranged in a stack includes, but is not limited to, a method for forming an oxide semiconductor device such as an etch stop layer (ESL) TFT, a back channel etch (BCE) TFT, a top gate TFT or the like.

In some embodiments, the first transistor T1 and/or the second transistor T2 are N-type metal oxide semiconductor transistors, hereinafter referred to as NMOS transistors.

In the embodiments of the present disclosure, both the first transistor T1 and the second transistor T2 are NMOS transistors as an example, and specific structures of the first transistor T1 and the second transistor T2 are described.

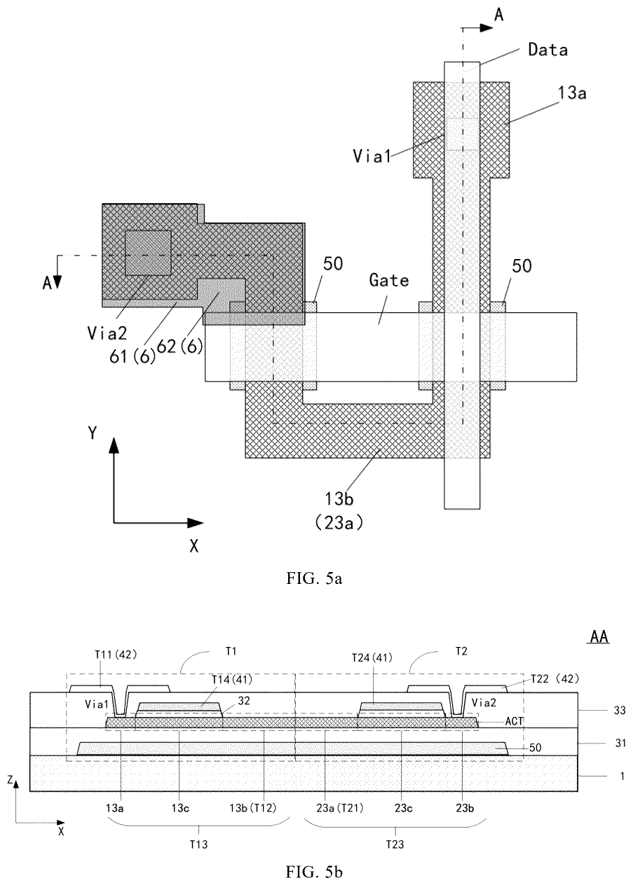

In some embodiments, FIG. 5a is a top plan view of a transistor with a top gate structure according to an embodiment of the present disclosure; FIG. 5b is a cross-sectional view of the structure shown in FIG. 5a along a direction AA. As shown in FIGS. 5a and 5b, the first transistor T1 and the second transistor T2 each may be a transistor with a top gate structure. A gate electrode T14 of the first transistor T1 is located on a side of the active layer T13 of the first transistor T1 away from the base substrate 1, a gate electrode T24 of the second transistor T2 is located on a side of the active layer T23 of the second transistor T2 away from the base substrate 1, the active layer T13 of the first transistor T1 includes the first contact portion 13a and the second contact portion 13b, and a first channel portion 13c between the first contact portion 13a and the second contact portion 13b, and the active layer T23 of the second transistor T2 includes the third contact portion 23a and the fourth contact portion 23b and a second channel portion 23c between the third contact portion 23a and the fourth contact portion 23b.

The first contact portion 13a, the second contact portion 13b, the third contact portion 23a, and the fourth contact portion 23b are conductive portions formed by conductorizing the active layer, and have a conductivity higher than that of the first channel portion 13c (and higher than that of the second channel portion 23c), and lower than that of the metal electrode. As a specific conductorization process, for example, plasma of a gas (including a mixed gas) such as He, Ar, H₂, or NH₃ may be selected for the conductive doping, thereby forming the first contact portion 13a, the second contact portion 13b, the third contact portion 23a, and the fourth contact portion 23b.

Illustratively, as shown in FIGS. 5a and 5b, the active layer T13 of the first transistor T1 and the active layer T23 of the second transistor T2 are disposed in the same layer. The second contact portion 13b is further used as the second electrode T12 of the first transistor T1, the third contact portion 23a is further used as the first electrode T21 of the second transistor T2, and the second contact portion 13b and the third contact portion 23a are connected together to have a one-piece structure. The first electrode T11 of the first transistor T1 is electrically connected to the first contact portion 13a and the data line Data through the first via Via1, respectively. The second electrode T22 of the second transistor is electrically connected to the fourth contact portion 23b and the fifth portion 61 of the auxiliary component 6 through the second via Via2, respectively.

Compared with a transistor with a bottom gate structure, the transistor with the top gate structure has the advantages of simple manufacturing process, less required lithography plates and low cost.

FIG. 6a is a schematic diagram of a plane where an active layer shown in FIG. 5b is located; FIG. 6b is a schematic diagram of a plane where a first conductive layer shown in FIG. 5b is located; FIG. 6c is a schematic diagram of a plane where first and second vias shown in FIG. 5b are located; FIG. 6d is a schematic diagram of a plane where a second conductive layer shown in FIG. 5b is located.

Illustratively, as shown in FIG. 5b, the display substrate further includes a first insulating layer 31 on the base substrate 1; a semiconductor layer ACT on a side of the first insulating layer 31 away from the base substrate 1 (as shown in FIG. 6a); a second insulating layer 32 on a side of the semiconductor layer ACT away from the first insulating layer 31; a first conductive layer 41 on a side of the second insulating layer 32 away from the semiconductor layer ACT (as shown in FIG. 6b); a third insulating layer 33 on a side of the first conductive layer 41 away from the second insulating layer 32; a second conductive layer 42 on a side of the third insulating layer 33 away from the first conductive layer 41 (as shown in FIGS. 6c and 6d). The gate electrode T14 of the first transistor T1 and the gate electrode T24 of the second transistor T2 are both located in the first conductive layer 41, the active layer T13 of the first transistor T1 (including the second contact portion 13b used as the second electrode T12 of the first transistor T1) and the active layer T23 of the second transistor T2 (including the third contact portion 23a used as the first electrode T21 of the second transistor T2) are both located in the semiconductor layer ACT, and the first electrode T11 of the first transistor T1 and the second electrode T22 of the second transistor T2 are both located in the second conductive layer 42.

In some embodiments, as shown in FIG. 5a, an outline of an orthographic projection of a pattern formed by the first channel portion 13c, the second contact portion 13b and third contact portion 23a having a one-piece structure, and the second channel portion 23c on the base substrate 1 has a U shape.

In some embodiments, FIG. 7 is a top plan view of a plurality of pixel units according to an embodiment of the present disclosure. As shown in FIG. 7, the first electric pole 22 is a pixel electrode ITO. An orthographic projection of the second contact portion 13b and the third contact portion 23a having a one-piece structure on the base substrate 1 partially overlaps with an orthographic projection of at least one pixel electrode ITO on the base substrate 1.

Illustratively, the active layer is a light-transmitting layer, and a region corresponding to an orthographic projection of the pixel electrode ITO is a display light-transmitting region, so that orthographic projections of the contact portions of the active layers and the pixel electrode ITO overlap with each other, which does not influence display light emission. The orthographic projections of the second contact portion 13b and the third contact portion 23a having a one-piece structure on the base substrate 1 partially overlap with the orthographic projection of at least one pixel electrode ITO on the base substrate 1, so that the layout space of each pixel unit 2 is reduced, thereby improving the resolution.

In some embodiments, as shown in FIG. 7, two pixel units 2 adjacently disposed along the column direction are shown. The orthographic projection of the second contact portion 13b and the third contact portion 23a having a one-piece structure in one of the two pixel units 2 on the base substrate 1 partially overlaps with an orthographic projection of the pixel electrode ITO of the other pixel unit 2 on the base substrate 1.

Alternatively, two pixel units 2 arranged adjacently along the row direction may also be provided. The orthographic projection of the second contact portion 13b and the third contact portion 23a having a one-piece structure in one of the two pixel units 2 on the base substrate 1 partially overlaps with an orthographic projection of the pixel electrode ITO of the other pixel unit 2 on the base substrate 1.

In some embodiments, as shown in FIG. 7, the display substrate further includes the data lines Data. Each data line Data is electrically connected to the first electrode T11 of the corresponding first transistor T1. An orthographic projection of each data line Data on the active layer T13 of the first transistor T1 passes through the active layer T13 of the first transistor T1 in a direction from the first contact portion 13a to the second contact portion 13b (i.e., a direction opposite to the Y direction), and an edge of an outline of the orthographic projection of each data line Data on the active layer T13 of the first transistor T1 is at a distance from an edge of the active layer T13 of the first transistor T1 in a width direction X of the data line Data. With such the structural arrangement of the present embodiment, the layout space of each pixel unit 2 is reduced, thereby improving the resolution.

On the basis, in combination with the layout structure of the pixel electrode ITO, an orthographic projection of the pixel electrode ITO on the second contact portion 13b and the third contact portion 23a having a one-piece structure does not fall into the orthographic projection of the corresponding data line Data on the active layer, so as to further improve the pixel resolution.

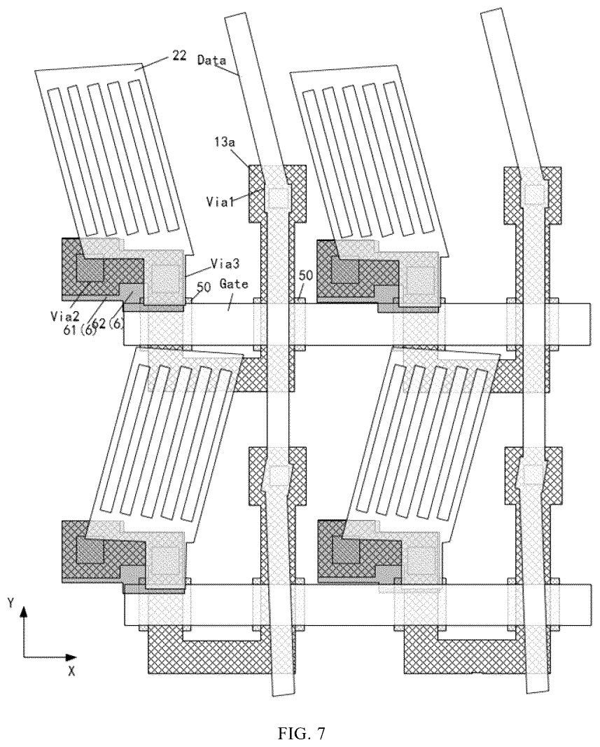

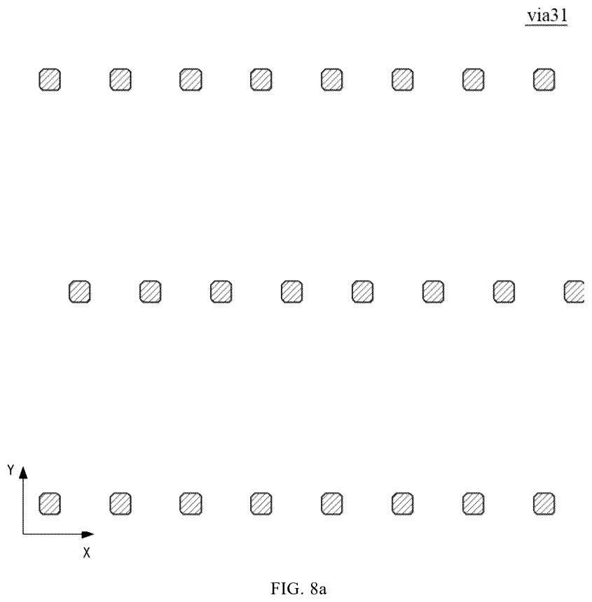

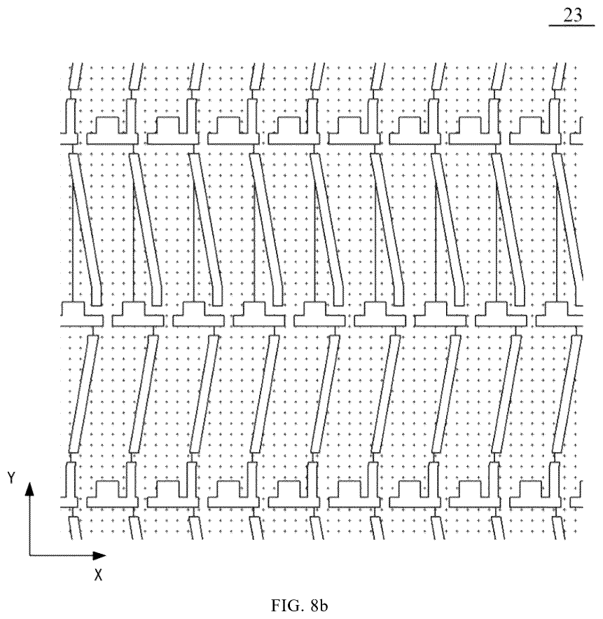

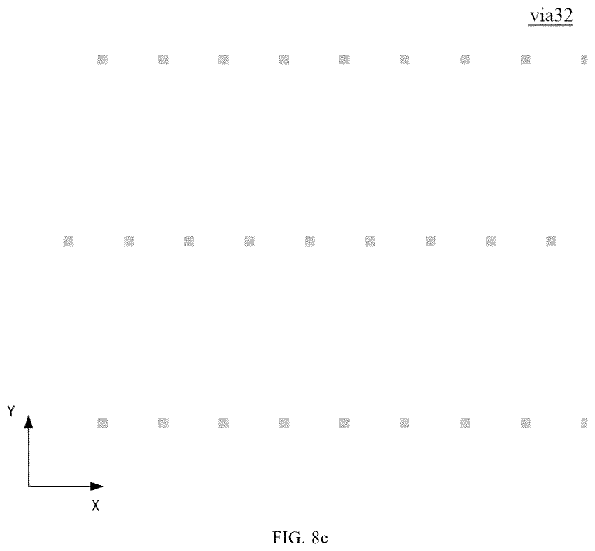

FIG. 8a is a schematic diagram of a plane where first sub-vias are located; FIG. 8b is a schematic diagram of a plane where a second electrode is located; FIG. 8c is a schematic diagram of a plane where second sub-vias are located; FIG. 8d is a schematic diagram of a plane where a first electrode is located.

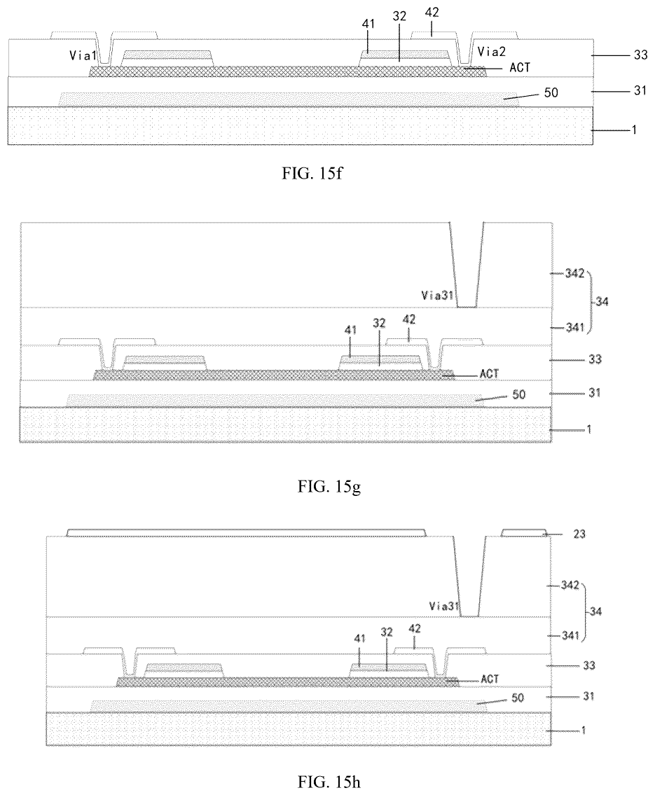

In some embodiments, as shown in FIGS. 15j and 8b, each pixel unit 2 further includes a second electric pole 23 located on a side of the pixel electrode ITO close to the base substrate 1. The second electric pole 23 is a common electrode.

In some embodiments, as shown in FIG. 8d, the pixel electrode ITO is a slit electrode, and the common electrode is a plate electrode. The pixel electrode ITO is electrically connected to the auxiliary component 6 through the third via Via3, and the auxiliary component 6 is electrically connected to the fourth contact portion 23b through the second via Via2. As shown in FIGS. 8a and 8c, the third via Via3 includes a first sub-via Via31 extending through a planarization layer 342, and a second sub-via Via32 extending through a metal protection layer 341. The pixel electrode ITO is electrically connected to the auxiliary component 6 sequentially through the first sub-via Via31 and the second sub-via Via32.

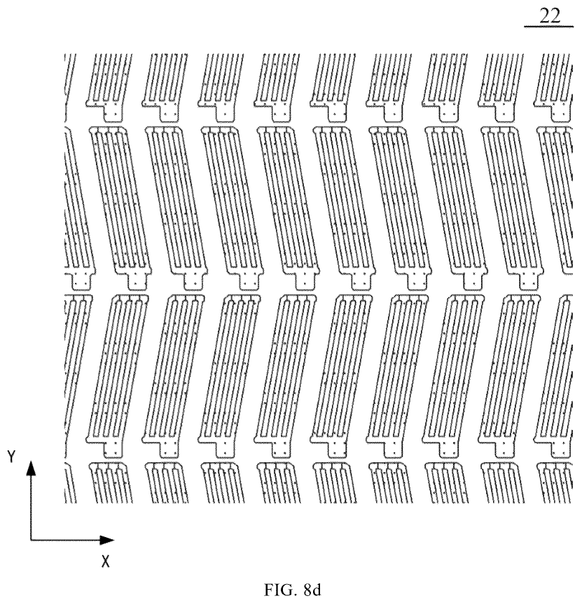

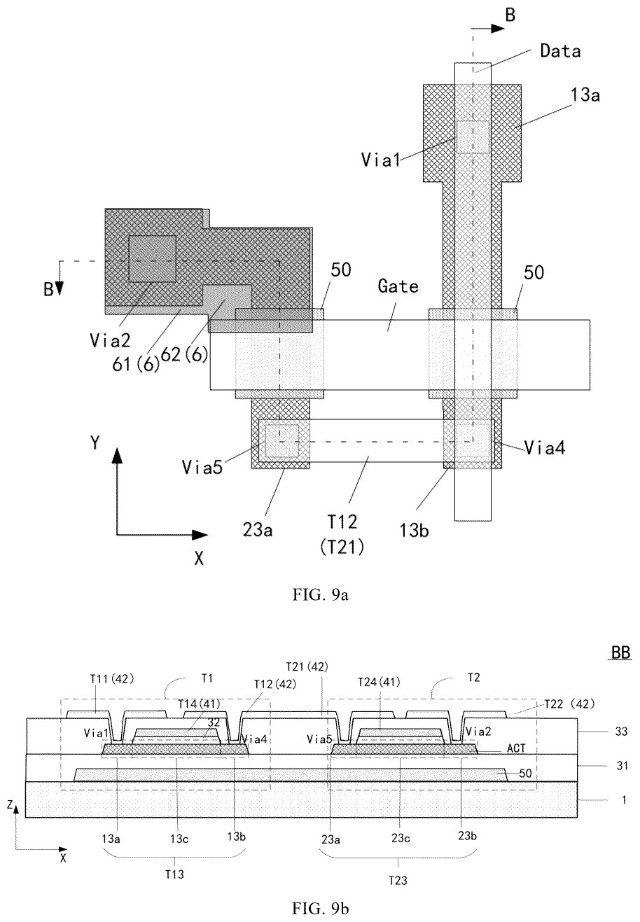

In some embodiments, FIG. 9a is a schematic diagram of a structure of another transistor with a top gate structure according to an embodiment of the present disclosure; FIG. 9b is a cross-sectional view of a structure shown in FIG. 9a along a direction BB. As shown in FIGS. 9a and 9b, the gate electrode T14 of the first transistor T1 and the gate electrode T24 of the second transistor T2 are disposed in the same layer; the active layer T13 of the first transistor T1 and the active layer T23 of the second transistor T2 are disposed in the same layer; the first electrode T11 and the second electrode of the first transistor T1 are disposed in the same layer as the first electrode T21 and the second electrode of the second transistor T2; the gate electrode T14 of the first transistor Tl is located on a side of the active layer away from the base substrate 1; the first electrode T11 and the second electrode of the first transistor T1 are located on a side of the gate electrode away from the active layer; the active layer T13 of the first transistor T1 includes the first contact portion 13a and the second contact portion 13b, and the first channel portion 13c between the first contact portion 13a and the second contact portion 13b; and the active layer T23 of the second transistor T2 includes the third contact portion 23a and the fourth contact portion 23b and the second channel portion 23c between the third contact portion 23a and the fourth contact portion 23b.

The first contact portion 13a, the second contact portion 13b, the third contact portion 23a, and the fourth contact portion 23b are conductive portions formed by conductorizing the active layers, and have a conductivity higher than the first channel portion 13c (and higher than that of the second channel portion 23c), and lower than the metal electrode. As a specific conductorization process, for example, plasma of a gas (including a mixed gas) such as He, Ar, H₂, or NH₃ may be selected for the conductive doping, thereby forming the first contact portion 13a, the second contact portion 13b, the third contact portion 23a, and the fourth contact portion 23b.

The second electrode T12 of the first transistor T1 and the first electrode T21 of the second transistor T2 are connected together to have a one-piece structure, the second electrode T12 of the first transistor T1 is electrically connected to the second contact portion 13b through a fourth via Via4, and the first electrode T21 of the second transistor T2 is electrically connected to the third contact portion 23a through a fifth via Via5. The first electrode T11 of the first transistor T1 is electrically connected to the first contact portion 13a and the data line Data through the first via Via1, respectively. The second electrode T22 of the second transistor is electrically connected to the fourth contact portion 23b and the fifth portion 61 of the auxiliary component 6, respectively, through the second via Via2.

The transistor having the top gate structure shown in FIG. 9b is different from the transistor having the top gate structure shown in FIG. 5b in the series connection mode. Compared with the transistor having the top gate structure shown in FIG. 5b, the transistor having the top gate structure shown in FIG. 9b realizes the series connection by using the metal electrode (the second electrode T12 of the first transistor T1 and the first electrode T21 of the second transistor T2 having a one-piece structure). The metal electrode has higher conductivity than the conductorized second contact portion 13b and the third contact portion 23a, so that the transistor having the top gate structure shown in FIG. 9b has a higher device stability.

Illustratively, as shown in FIG. 9b, the display substrate further includes a first insulating layer 31 on the base substrate 1; a semiconductor layer ACT on a side of the first insulating layer 31 away from the base substrate 1; a second insulating layer 32 on a side of the semiconductor layer ACT away from the first insulating layer 31; a first conductive layer 41 on a side of the second insulating layer 32 away from the semiconductor layer ACT; a third insulating layer 33 on a side of the first conductive layer 41 away from the second insulating layer 32; a second conductive layer 42 on a side of the third insulating layer 33 away from the first conductive layer 41. The gate electrode T14 of the first transistor T1 and the gate electrode T24 of the second transistor T2 are both located in the first conductive layer 41, the active layer T13 of the first transistor T1 and the active layer T23 of the second transistor T2 are both located in the semiconductor layer ACT, and the first electrode T11 and the second electrode T12 of the first transistor T1 and the first electrode T21 and the second electrode T12 of the second transistor T2 are both located in the second conductive layer 42.

For example, as shown in FIG. 9b, the first insulating layer 31 may be a buffer insulating layer. The buffer insulating layer may be provided in a single-layer structure made of a SiOx (x>0) material, or in a composite-layer structure made of SiN/SiOx (x>0) materials.

For example, as shown in FIG. 9b, the first insulating layer 31 may be a dielectric layer disposed between the light shielding layer 50 and the semiconductor layer ACT, and may have other effects besides the light shielding effect. One effect is the electrical effect: the light shielding layer 50 is conductive, and charges are induced in the device including the floating light shielding layer 50 so that the transistor is turned on in advance, the threshold voltage Vth is reduced. The thinner the first insulating layer 31 is, the greater the effect is. For the device of the light shielding layer connected to the gate electrode, the first insulating layer 31 needs to be thinned to provide higher Ion capability, and in general, the first insulating layer 31 should have the appropriate thickness for electrical requirements. The other effect is process coverage effects: the first insulating layer 31 necessarily has a certain thickness to ensure isolation, and prevent the active layer from breaking or short-circuiting at the edge of the light shielding layer 50, and the thickness of the first insulating layer 31 is set to be in a range from 200 nm to 500 nm.

For example, as shown in FIG. 9b, the second insulating layer 32 may be a gate insulating layer, which may be generally made of the SiOx (x>0) material.

Illustratively, as shown in FIG. 9b, unlike the first insulating layer 31, the second insulating layer 32 is between the first conductive layer 41 and the semiconductor layer ACT. For electrical properties, the thinner the second insulating layer 32 is, the higher the Ion capability is. In addition, the second insulating layer 32 is not required to provide the covering and protecting function in the process for manufacturing the top gate structure, and the electrical breakdown caused by the too thin layer is avoided by taking into account the process capability, so that the thickness of the second insulating layer 32 is set to be between 100 nm and 300 nm. For example, as shown in FIG. 9 b, the first conductive layer 41 may be of a single-layer structure, and made of Al or Cu. Still alternatively, the first conductive layer 41 may be of a composite-layer structure, which may include a buffer layer and a main conductive layer, where the buffer layer may be made of a Ti-based alloy material or a Mo-based alloy material, and the main conductive layer may be made of Al or Cu. Alternatively, the first conductive layer 41 may have a single-layer structure, and made of a Ti-based alloy material or a Mo-based alloy material, or the like added to Al or Cu.

Illustratively, as shown in FIG. 9b, the third insulating layer 33 is an intermediate dielectric layer, which may be a single-layer structure made of the SiOx (x>0) material. Alternatively, the intermediate dielectric layer may be of a composite-layer structure made of the SiN/SiOx (x>0) materials.

Illustratively, as shown in FIG. 9b, the third insulating layer 33 is configured to separate a gate electrode from a source/drain electrode in a longitudinal section of the device, and a certain thickness is required between the gate electrode and the source/drain electrode to prevent short circuit failure and reduce a capacitance between metals, and prevent a pull load between electrical signals. The intermediate dielectric layer is too thick to facilitate the stability of the engineering contact, so the thickness of the third insulating layer 33 is set to be in a range from 300 nm to 600 nm.

Illustratively, as shown in FIG. 9b, the material of the second conductive layer 42 is a metal.

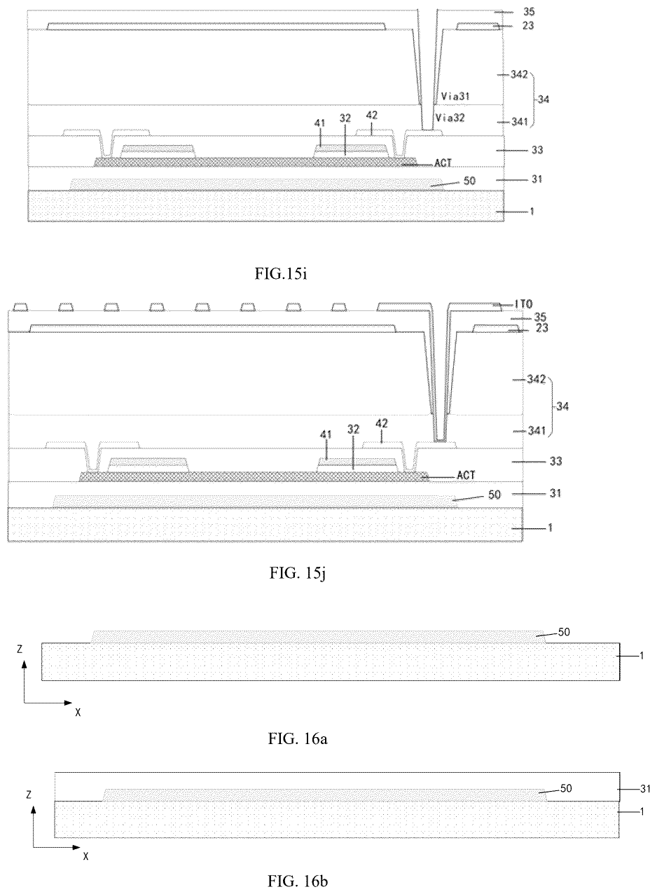

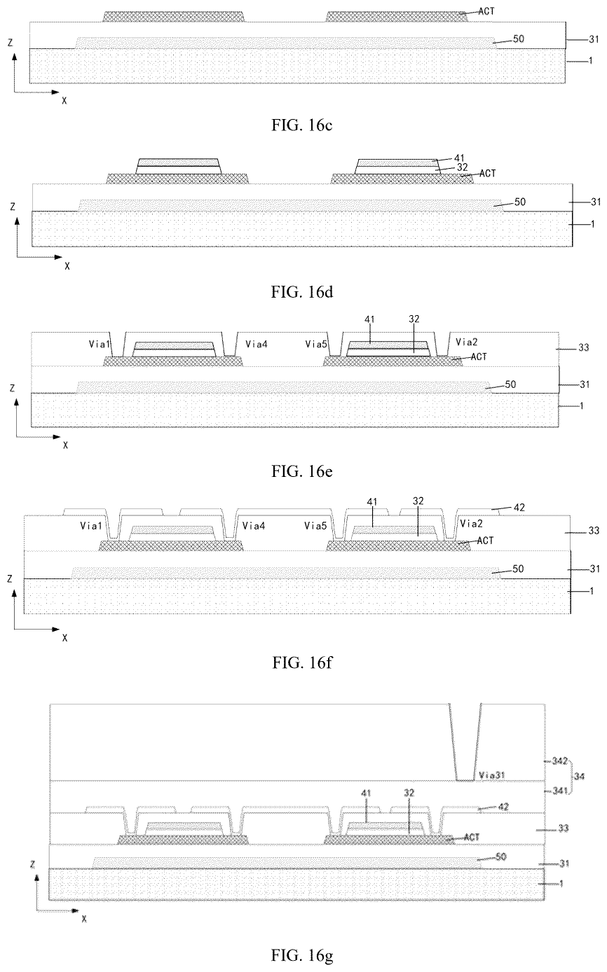

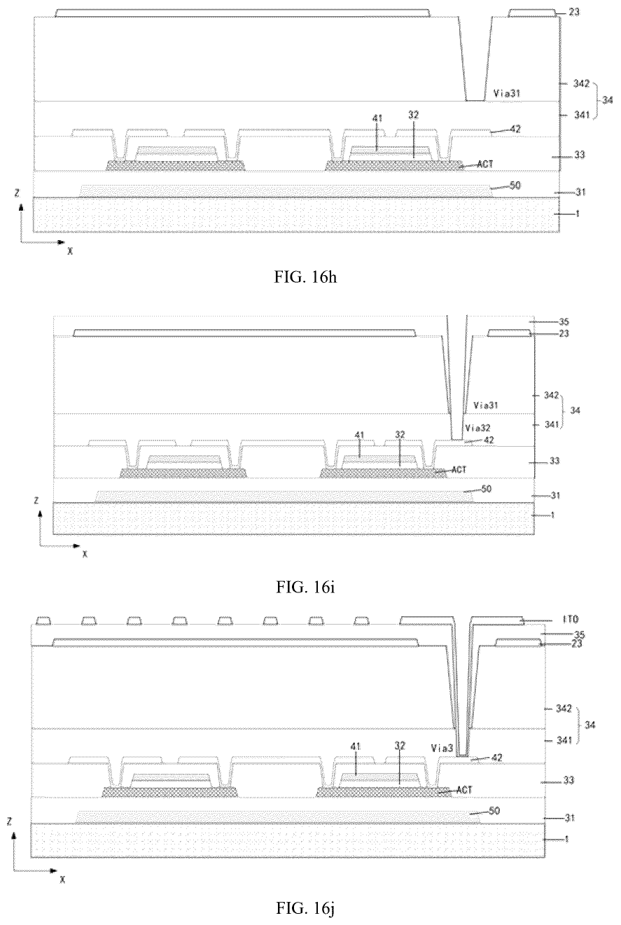

Illustratively, as shown in FIGS. 16j and 8a to 8d, the top gate structure shown in FIG. 9b is connected to the pixel electrode ITO. The pixel electrode ITO is electrically connected to the auxiliary component 6 through the third via Via3, and the auxiliary component 6 is electrically connected to the fourth contact portion 23b through the second via Via2. As shown in FIGS. 8a and 8c, the third via Via3 includes a first sub-via Via31 extending through the planarization layer 342, and a second sub-via Via32 extending through the metal protection layer 341. The pixel electrode ITO is electrically connected to the auxiliary component 6 sequentially through the first sub-via Via31 and the second sub-via Via32.

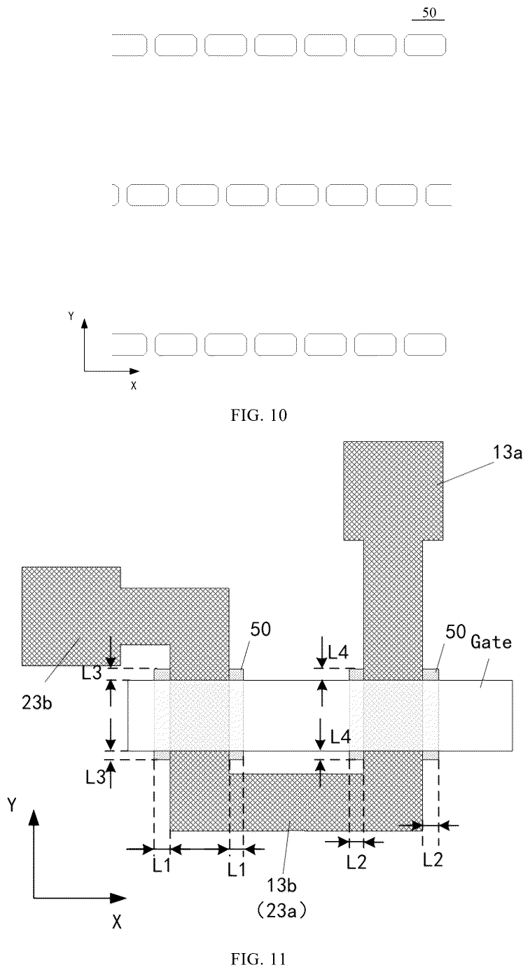

FIG. 10 is a top view of a plane where a light shielding layer is located. Both the top gate structure shown in FIG. 5b and the top gate structure shown in FIG. 9b include the light shielding layer 50. In some embodiments, as shown in FIGS. 5b, 9b and 10, the display substrate further includes the light shielding layer 50 disposed on a side of the pixel unit 2 close to the base substrate 1.

For example, the light shielding layer 50 may be of a composite-layer structure, which includes a composite layer with Mo-based alloy/Cu material or a composite layer with Mo-based alloy/Al material.

As shown in FIG. 5a or 9a, an orthographic projection of the light shielding layer 50 on the base substrate 1 at least covers orthographic projections of the first channel portion 13c of the active layer T13 of the first transistor T1 and the second channel portion 23c of the active layer T23 of the second transistor T2 on the base substrate 1.

In this embodiment, the light shielding layer 50 is arranged to shield light emitted from a backlight source onto the first channel portion 13c and the second channel portion 23c, so that the number of electron-hole pairs generated by the first contact portion 13a (or the third contact portion 23a) due to light illumination can be reduced, and the number of electrons moving to the second contact portion 13b (or the fourth contact portion 23b) during a maintenance stage is reduced, thereby reducing light leakage current and solving the flicker problem caused by the leakage current.

In some embodiments, FIG. 11 is a top plan view of an exemplary light shielding layer according to an embodiment of the present disclosure. As shown in FIG. 11, there is a maximum first distance between an edge of an outline of an orthographic projection of the light shielding layer 50 on the base substrate 1 and an edge of an outline of an orthographic projection of the first channel portion 13c on the base substrate 1, and there is a maximum second distance between the edge of the outline of the orthographic projection of the light shielding layer 50 on the base substrate 1 and an edge of an outline of an orthographic projection of the second channel portion 23c on the base substrate 1. The maximum first distance and/or the maximum second distance is/are in a range from 4 μm to 6 μm.

Illustratively, as shown in FIG. 11, in the first direction X, there is the maximum first distance L1 in a range from 4 μm to 6 μm between the edge of the outline of the orthographic projection of the light shielding layer 50 on the base substrate 1 and the edge of the outline of the orthographic projection of the first channel portion 13c on the base substrate 1. The direction from the first contact portion 13a to the second contact portion 13b is the current flowing direction (i.e., the direction opposite to the Y direction). Thus, in order to avoid forming a current path between opposite side portions of the first channel portion 13c in the first direction X, a width of the light shielding layer 50 in the first direction X is set to be slightly larger, which ensures that the first channel portion 13c is not affected by light irradiation in the first direction X, thereby ensuring the stability of the first transistor T1. Similarly, in the first direction X, there is the maximum second distance L2 in a range from 4 μm to 6 μm between the edge of the outline of the orthographic projection of the light shielding layer 50 on the base substrate 1 and the edge of the outline of the orthographic projection of the second channel portion 23c on the base substrate 1. The direction from the third contact portion 23a to the fourth contact portion 23b is the current flowing direction, that is, the second direction Y. In order to avoid forming a current path between opposite side portions of the second channel portion 23c in the first direction X, the width of the light shielding layer 50 in the first direction X is set to be slightly larger, which ensures that the second channel portion 23c is not affected by light irradiation in the first direction X, thereby ensuring the stability of the second transistor T2.

Illustratively, as shown in FIG. 11, in the second direction, there is a third distance L3 in a range from 0 μm to 4 μm between the edge of the outline of the orthographic projection of the light shielding layer 50 on the base substrate 1 and the edge of the outline of the orthographic projection of the first channel portion 13c on the base substrate 1. In the second direction Y, there is a fourth distance L4 in a range from 0 μm to 4 μm between the edge of the outline of the orthographic projection of the light shielding layer 50 on the base substrate 1 and the edge of the outline of the orthographic projection of the second channel portion 23c on the base substrate 1. The light shielding layer 50 is opaque, so that an area covered by the light shielding layer 50 should be as small as possible. However, in order to ensure the stability of the device, the area covered by the light shielding layer 50 should be as large as possible. Therefore, considering the influence of the pixel specification and the device stability sufficiently, the width of the light shielding layer 50 in the second direction Y is set to be slightly smaller to improve the light transmittance.

In some embodiments, as shown in FIG. 5a or FIG. 9a, the pixel units 2 in the same row are electrically connected to the same gate line Gate. Each gate line Gate serves as the gate electrode T14 of the corresponding first transistor T1 and the gate electrode T24 of the corresponding second transistor T2.

The gate lines Gate in this embodiment are further used as the gate electrodes of the transistors. Such the in-plane routing can realize a narrow border.

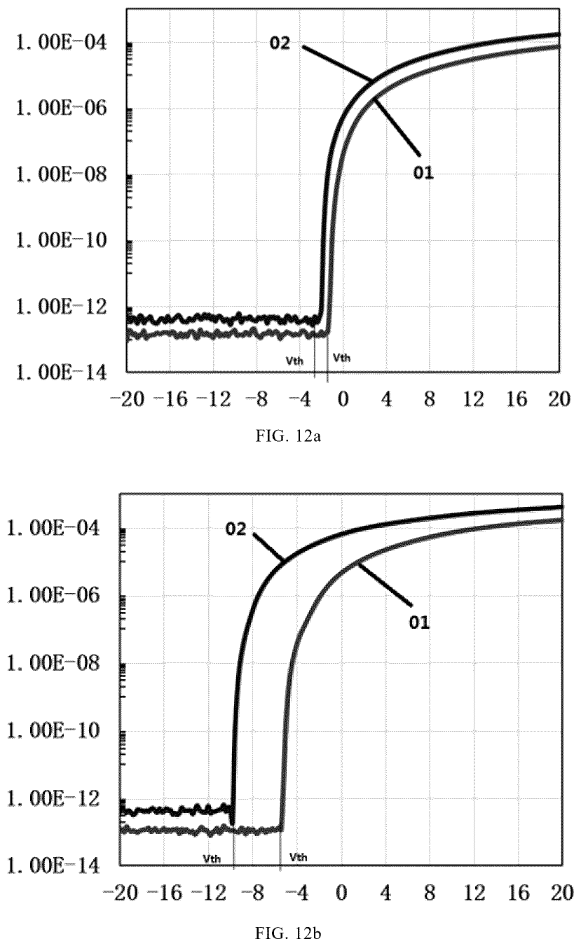

FIG. 12a shows performance test results of a dual NMOS transistor device shown in FIG. 9b in a normal operating state (−1.5V); FIG. 12b shows performance test results of a dual NMOS transistor device shown in FIG. 9b in a negative bias state (−8V). The abscissa Vg represents voltages at the gate electrode T14 (i.e., the gate line Gate) of the first transistor T1 and the gate electrode T24 (i.e., the gate line Gate) of the second transistor T2, the ordinate Ids represents a current through the first electrode T11 (i.e., the drain electrode) of the first transistor T1, Vth represents the threshold voltage, 01 represents a curve for the dual NMOS structure shown in FIG. 9b, and 02 represents a curve for a single NMOS structure. As can be seen from FIGS. 9a and 9b, compared to the single NMOS structure, whether in the normal operating state or the negative bias state, the off-state current of the dual NMOS structure is relatively lower, and the threshold voltage of the dual NMOS structure is relatively large. Therefore, compared with the prior art, the embodiment of the present disclosure can effectively solve the problem of electric leakage of the whole device and the Mura problem of the display product caused by the electric leakage.

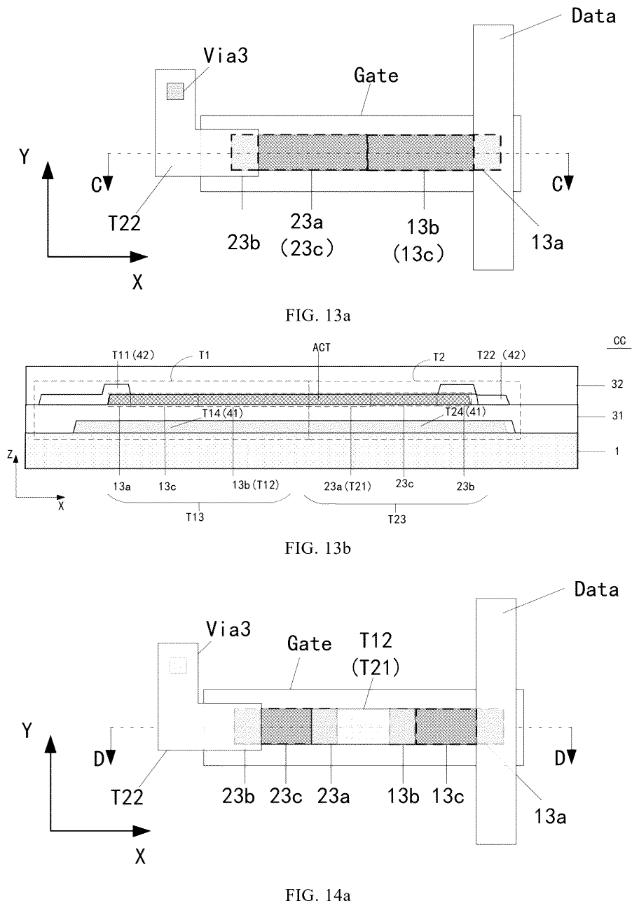

In some embodiments, the first transistor T1 and the second transistor T2 may employ transistors of a bottom gate structure. FIG. 13a is a schematic diagram of a structure of a transistor with a bottom gate structure according to an embodiment of the present disclosure; FIG. 13b is a cross-sectional view of a structure shown in FIG. 13a along a direction CC. As shown in FIG. 13a and FIG. 13b, the gate electrode T14 of the first transistor T1 and the gate electrode T24 of the second transistor T2 are disposed in the same layer; the active layer T13 of the first transistor T1 and the active layer T23 of the second transistor T2 are disposed in the same layer; the first electrode T11 of the first transistor T1 is disposed in the same layer as the second electrode T22 of the second transistor T2; the gate electrode T14 of the first transistor T1 is located on a side of the active layer close to the base substrate 1; the first electrode T11 of the first transistor T1 is located on a side of the active layer T13 away from the gate electrode T14; the active layer T13 of the first transistor T1 includes the first contact portion 13a and the second contact portion 13b, and the second contact portion 13b is further used as the first channel portion 13c of the first transistor T1; the active layer T23 of the second transistor T2 includes the third contact portion 23a and the fourth contact portion 23b, and the third contact portion 23a is further used as the second channel portion 23c of the second transistor T2.

The first contact portion 13a and the fourth contact portion 23b are conductive portions formed by conductorizing the active layers, and have a conductivity higher than that of the first channel portion 13c (and higher than that of the second channel portion 23c), and lower than that of the metal electrode. As a specific conductorization process, for example, plasma of a gas (including a mixed gas) such as He, Ar, H₂, or NH₃ may be selected for the conductive doping, thereby forming the first contact portion 13a and the fourth contact portion 23b.

As shown in FIG. 13a, the second contact portion 13b and the third contact portion 23a are connected together to have a one-piece structure.

As shown in FIG. 13a, each data line Data is further used as the first electrode T11 of the corresponding first transistor T1. The second electrode T22 of the second transistor T2 is electrically connected to the first electric pole 22 through the third via Via3.

In the embodiment of the present disclosure, whether the transistors of the bottom gate structure or the transistors of the top gate structure, the dual transistors may be connected in series by using the second contact portion 13b and the third contact portion 23a having a one-piece structure.

Compared with the transistor with the top gate structure, in the transistor with the bottom gate structure, the gate electrode on a side of the active layer close to the base substrate 1 may be further used as an optical protective film of the active layer, which can prevent carriers generated by light emitted by a backlight source from irradiating the active layer and damaging the electrical characteristics of the active layer, so that the transistor with the bottom gate structure has a more stable device performance than the transistor with the top gate structure. In addition, in the present embodiment, the second contact portion 13b and the third contact portion 23a are connected together to have a one-piece structure. That is, the first channel portion 13c and the second channel portion 23c are connected together to have a one-piece structure, so that a channel length of the transistor is increased, and the conductorization is not easily to occur.

Illustratively, as shown in FIG. 13b, the display substrate further includes the first conductive layer 41 on the base substrate 1; the first insulating layer 31 on a side of the first conductive layer 41 away from the base substrate 1; the semiconductor layer ACT on a side of the first insulating layer 31 away from the first conductive layer 41; the second conductive layer 42 on a side of the semiconductor layer ACT away from the first insulating layer 31; and the second insulating layer 32 on a side of the second conductive layer 42 away from the semiconductor layer ACT. The gate electrode T14 of the first transistor T1 and the gate electrode T24 of the second transistor T2 are both located in the first conductive layer 41; the active layer T13 of the first transistor T1 (including the second contact portion 13b further used as the second electrode T12 of the first transistor T1) and the active layer T23 of the second transistor T2 (including the third contact portion 23a further used as the first electrode T21 of the second transistor T2) are both located in the semiconductor layer ACT; and the first electrode T11 of the first transistor T1 and the second electrode T22 of the second transistor T2 are both located in the second conductive layer 42.

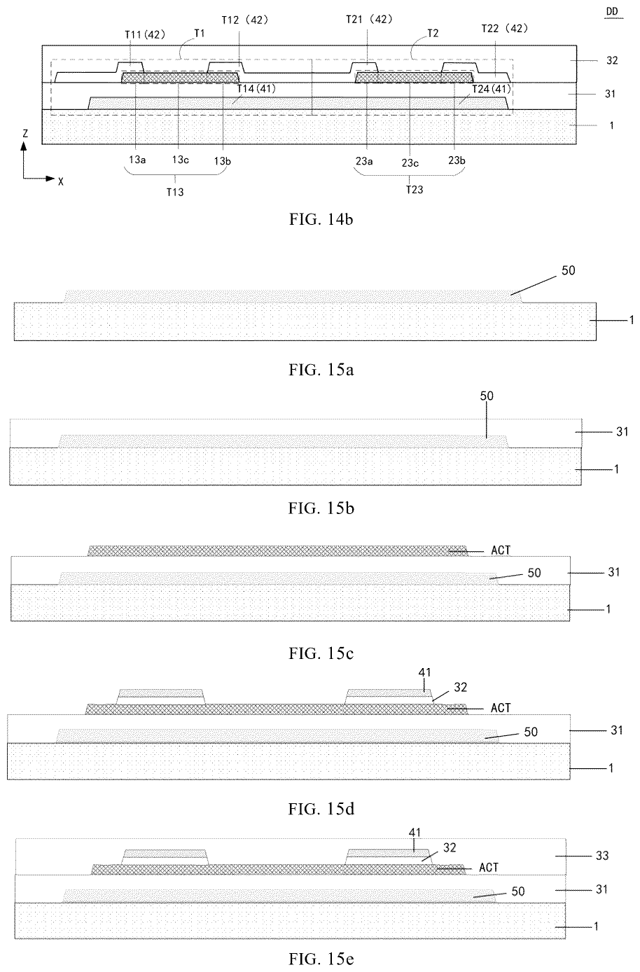

In some embodiments, FIG. 14a is another schematic diagram of a structure of a transistor with a bottom gate structure according to an embodiment of the present disclosure; FIG. 14b is a cross-sectional view of a structure shown in FIG. 14a along a direction DD. As shown in FIG. 14a and FIG. 14b, the gate electrode T14 of the first transistor T1 and the gate electrode T24 of the second transistor T2 are disposed in the same layer; the active layer T13 of the first transistor T1 and the active layer T23 of the second transistor T2 are disposed in the same layer; the first electrode T11 and the second electrode T12 of the first transistor T1 are disposed in the same layer as the first electrode T21 and the second electrode T22 of the second transistor T2; the gate electrode T14 of the first transistor T1 is located on a side of the active layer close to the base substrate 1; the first electrode T11 and the second electrode T12 of the first transistor T1 are located on a side of the active layer away from the gate electrode; the active layer T13 of the first transistor T1 includes the first contact portion 13a and the second contact portion 13b, and the first channel portion 13c between the first contact portion 13a and the second contact portion 13b; and the active layer T23 of the second transistor T2 includes the third contact portion 23a and the fourth contact portion 23b and the second channel portion 23c between the third contact portion 23a and the fourth contact portion 23b.

The first contact portion 13a, the second contact portion 13b, the third contact portion 23a, and the fourth contact portion 23b are conductive portions formed by conductorizing the active layers, and have a conductivity higher than that of the first channel portion 13c (and higher than that of the second channel portion 23c), and lower than that of the metal electrode. As a specific conductorization process, for example, plasma of a gas (including a mixed gas) such as He, Ar, H₂, or NH₃ may be selected for conductorization doping, thereby forming the first contact portion 13a, the second contact portion 13b, the third contact portion 23a, and the fourth contact portion 23b.

As shown in FIG. 14a, the second electrode T12 of the first transistor T1 and the first electrode T21 of the second transistor T2 are connected together to have a one-piece structure, and the second electrode T12 of the first transistor T1 is electrically connected to the second contact portion 13b of the first transistor T1. The first electrode T21 of the second transistor T2 is electrically connected to the third contact portion 23a of the second transistor T2.

As shown in FIG. 14a, each data line Data is further used as the first electrode T11 of the corresponding first transistor T1. The second electrode T22 of the second transistor T2 is electrically connected to the first electric pole 22 through the third via Via3.

The transistor having the bottom gate structure shown in FIG. 14b is different from the transistor having the bottom gate structure shown in FIG. 13b in the series connection mode. Compared with the transistor having the bottom gate structure shown in FIG. 13b, the transistor having the bottom gate structure shown in FIG. 14b realizes the series connection by using the metal electrode (the second electrode T12 of the first transistor T1 and the first electrode T21 of the second transistor T2 having a one-piece structure). The metal electrode has higher conductivity than the conductorized second contact portion 13b and the third contact portion 23a, so that the transistor having the bottom gate structure shown in FIG. 14b has higher device stability. In addition, in the embodiment, two transistors are connected in series, and if one of the two transistors is abnormal in turn-off due to the conductorization, the other transistor can also operate normally.

Illustratively, as shown in FIG. 14b, the display substrate further includes the first conductive layer 41 on the base substrate 1; the first insulating layer 31 on a side of the first conductive layer 41 away from the base substrate 1; the semiconductor layer ACT on a side of the first insulating layer 31 away from the first conductive layer 41; the second conductive layer 42 on a side of the semiconductor layer ACT away from the first insulating layer 31; and the second insulating layer 32 on a side of the second conductive layer 42 away from the semiconductor layer ACT. The gate electrode T14 of the first transistor T1 and the gate electrode T24 of the second transistor T2 are both located in the first conductive layer 41; the active layer T13 of the first transistor T1 and the active layer T23 of the second transistor T2 are both located in the semiconductor layer ACT; and the first electrode T11 and the second electrode of the first transistor T1 and the first electrode T21 and the second electrode of the second transistor T2 are both located in the second conductive layer 42.

For example, the first conductive layer 41 may be a single-layer structure, and may be made of Al or Cu. Still alternatively, the first conductive layer 41 may be a composite layer structure, and include a buffer layer and a main conductive layer, where the buffer layer may be made of a Ti-based alloy material or a Mo-based alloy material, and the main conductive layer may be made of Al or Cu. Alternatively, the first conductive layer 41 may have a single-layer structure, and made of a Ti-based alloy material or a Mo-based alloy material, or the like added to Al or Cu.

For example, as shown in FIG. 13b or FIG. 14b, the first insulating layer 31 may be a gate insulating layer, which may be generally made of SiOx (x>0).

For example, as shown in FIG. 13b or FIG. 14b, in terms of the requirement of the coverage and the capacitance reduction of the gate electrode, the first insulating layer 31 as the gate insulating layer is required to provide the covering and protecting function in the process for manufacturing the bottom gate structure, and the thickness of the first insulating layer 31 as the gate insulating layer affects the capacitance, so that compared with the top gate structure, the thickness of the first insulating layer 31 as the gate insulating layer is greater. In addition, in view of the Ion capability, the thinner the first insulating layer 31 as the gate insulating layer is, the higher the Ion capability is. Therefore, in combination with the above two requirements, the thickness of the first insulating layer 31 may be in a range from 300 nm to 500 nm. Illustratively, as shown in FIG. 13b or FIG. 14b, the material of the second conductive layer 42 is a metal.

Illustratively, as shown in FIG. 13b or FIG. 14b, the second insulating layer 32 is a channel protection layer, which may be made of the SiOx (x>0) material, and the thickness of the second insulating layer 32 is not less than 100 nm.

For example, as shown in FIG. 13b or FIG. 14b, the second insulating layer 32 is a channel protection layer, which may be made of a composite layer of SiN and SiOx (x>0), and the overall thickness of the second insulating layer 32 is between 200 nm and 400 nm. In addition, the thickness of the second insulating layer 32 is not only required to cover the second conductive layer 42, but also required to protect TFT characteristics. For example, the thickness of the SiOx (x>0) layer is required to ensure that the device is not conductorized, and the SiN layer is used to block moisture from the organic layers (a moisture blocking capability of the SiN layer is better than that of the SiOx (x>0) layer) and so on.

In some embodiments, as shown in FIG. 13b or FIG. 14b, the pixel units 2 in the same row are electrically connected to the same gate line Gate; each gate line Gate serves as the gate electrodes T14 of the corresponding first transistors T1 and the gate electrodes T24 of the corresponding second transistors T2; the gate lines Gate are a composite layer, which includes a buffer layer and a main conductive layer which are sequentially disposed on the base substrate 1. The buffer layer may be made of a Ti-based alloy material or a Mo-based alloy material, and the main conductive layer may be made of Al or Cu.

In some embodiments, as shown in FIGS. 17i, 18i and 8b, each pixel unit 2 further includes the second electric pole 23 located on a side of the pixel electrode ITO close to the base substrate 1. The second electric pole 23 is a common electrode.

In some embodiments, as shown in FIG. 8d, the pixel electrode ITO is a slit electrode, and the common electrode is a plate electrode. The pixel electrode ITO is electrically connected to the second electrode T22 of the second transistor T2 through the third via Via3. As shown in FIGS. 8a and 8c, the third via Via3 includes the first sub-via Via31 extending through a planarization layer 342, and the second sub-via Via32 extending through the metal protection layer 341. The pixel electrode ITO is electrically connected to the second electrode T22 of the second transistor T2 sequentially through the first sub-via Via31 and the second sub-via Via32.

In addition, the embodiment of the present disclosure further provides a display apparatus, which includes the display substrate in any one of the embodiments. The display apparatus may be any product with a display function, such as a mobile phone, a tablet computer, a television, a display, a notebook computer, a digital photo frame, a vehicle-mounted device or the like. Other essential components of the display apparatus are understood by one of ordinary skill in the art, and are not described herein nor should they be construed as limiting the present disclosure.

In addition, the embodiments of the present disclosure further provide a method for manufacturing a display substrate, which is used for manufacturing the display substrate in any one of the above embodiments.

The method specifically includes: providing a base substrate 1; and forming a plurality of pixel units 2 arranged in an array on the base substrate 1. The forming each pixel unit 2 at least includes: sequentially forming a pixel circuit 21 and a first electric pole 22 on the base substrate 1. The pixel circuit 21 includes at least a first transistor T1 and a second transistor T2; a second electrode T12 of the first transistor T1 is electrically connected to a first electrode T21 of the second transistor T2, and a second electrode T22 of the second transistor T2 is electrically connected to the first electric pole 22. An active layer T13 of the first transistor T1 and an active layer T23 of the second transistor T2 are made of a metal oxide semiconductor material.

In some embodiments, FIGS. 15a to 15j are schematic diagrams illustrating a process for manufacturing a display substrate shown in FIG. 5b according to an embodiment of the present disclosure. The method specifically includes the following steps S11 to S111.

The step S11 includes providing the base substrate 1.

In this step, the base substrate 1 is a glass substrate.

The step S12 includes, as shown in FIG. 15a, forming the light shielding layer 50 on the base substrate 1.

The step S13 includes, as shown in FIG. 15b, forming the first insulating layer 31 on a side of the light shielding layer 50 away from the base substrate 1.

The step S14 includes, as shown in FIG. 15c, forming the semiconductor layer ACT on a side of the first insulating layer 31 away from the light shielding layer 50.

Specifically, a material of the semiconductor layer ACT is deposited, the material of the semiconductor layer ACT is selected from oxide materials with a high mobility such as IGZTO, IGO, or the like, and the material of the semiconductor layer ACT is then subjected to conventional annealing and patterning processes.

The step S15 includes, as shown in FIG. 15d, forming the second insulating layer 32 and the first conductive layer 41 on a side of the semiconductor layer ACT away from the first insulating layer 31.

The second insulating layer 32 is a gate insulating layer, and the first conductive layer 41 includes the gate electrodes, or the gate lines Gate further used as the gate electrodes.

A material of the gate insulating layer and a material of the first conductive layer 41 are sequentially deposited; and then, a lithography process for a gate electrode and an etching process are performed, the gate insulating layer is etched by using the gate electrode as a mask, to expose and then conductorize the semiconductor layer ACT. The conductorization process may be performed by plasma of a gas (including a mixed gas) such as He, Ar, H₂, or NH₃ or the like.

It should be noted that the conductorized second contact portion 13b is directly connected to the conductorized third contact portion 23a.

The step S16 includes, as shown in FIG. 15e, forming the third insulating layer 33 on the basis of the step S15.

A material of the second insulating layer 32 is deposited, and then a lithography process for an intermediate dielectric layer and an etching process are performed, to form the first via Via1 to the first contact portion 13a of the active layer and the second via Via2 to the fourth contact portion 23b.

The step S17 includes, as shown in FIG. 15f, forming the second conductive layer 42 on a side of the third insulating layer 33 away from the base substrate 1.

The material of the second conductive layer 42 is a metal material, and the second conductive layer 42 is electrically connected to the first contact portion 13a and the fourth contact portion 23b through the first via Via1 and the second via Via2 extending through the third insulating layer 33, respectively. The second contact portion 13b is further used as the second electrode T12 of the first transistor T1, and the third contact portion 23a is further used as the first electrode T21 of the second transistor T2.

The step S18 includes, as shown in FIG. 15g, forming the fourth insulating layer 34 on a side of the second conductive layer 42 away from the third insulating layer 33.

The fourth insulating layer 34 may include a metal protection layer 341 and a planarization layer 342.

Materials of the metal protection layer 341 and the planarization layer 342 are sequentially deposited, and a lithography process for an organic material is then performed on the planarization layer 342 to form the first sub-via Via31.

The step S19 includes, as shown in FIG. 15h, forming the second electric pole 23 on a side of the fourth insulating layer 34 away from the third insulating layer 33.

The second electric pole 23 is a common electrode.

The step S110 includes, as shown in FIG. 15i, forming the fifth insulating layer 35 on a side of the second electric pole 23 away from the fourth insulating layer 34.

The fifth insulating layer 35 is a passivation layer.

A material of the passivation layer is deposited, and a lithography process for the passivation layer and an etching process are then performed to form the second sub-via Via32 to the second electrode T22 of the second transistor T2.

The step S111 includes, as shown in FIG. 15j, forming the pixel electrode ITO on a side of the fifth insulating layer 35 away from the second electric pole 23.

The pixel electrode ITO is a slit electrode. The pixel electrode ITO has a connection portion connected to the auxiliary component 6 (i.e., the second electrode T22 of the second transistor T2) through the third via Via3; the auxiliary component 6 is connected to the fourth contact portion 23b through the second via Via2.

In some embodiments, FIGS. 16a to 16j are schematic diagrams illustrating a process for manufacturing a display substrate shown in FIG. 9b according to an embodiment of the present disclosure. The method specifically includes the following steps S21 to S211:
The step S21 includes providing the base substrate 1.

In this step, the base substrate 1 is a glass substrate.
The step S22 includes, as shown in FIG. 16a, forming the light shielding layer 50 on the base substrate 1.
The step S23 includes, as shown in FIG. 16b, forming the first insulating layer 31 on a side of the light shielding layer 50 away from the base substrate 1.
The step S24 includes, as shown in FIG. 16c, forming the semiconductor layer ACT on a side of the first insulating layer 31 away from the light shielding layer 50.

Specifically, a material of the semiconductor layer ACT is deposited, the material of the semiconductor layer ACT is selected from oxide materials with a high mobility such as IGZTO, IGO, or the like, and the material of the semiconductor layer ACT is then subjected to conventional annealing and patterning processes.
The step S25 includes, as shown in FIG. 16d, forming the second insulating layer 32 and the first conductive layer 41 on a side of the semiconductor layer ACT away from the first insulating layer 31.

The second insulating layer 32 is a gate insulating layer, and the first conductive layer 41 includes the gate electrodes, or the gate lines Gate further used as the gate electrodes.

A material of the gate insulating layer and a material of the first conductive layer 41 are sequentially deposited; and then, a lithography process and an etching process for a gate electrode are performed, the gate insulating layer is etched by using the gate electrode as a mask plate, to expose the semiconductor layer ACT which is then conductorized. The conductorization process may be performed by plasma of a gas (including a mixed gas) such as He, Ar, H₂, or NH₃ or the like.
The step S26 includes, as shown in FIG. 16e, forming the third insulating layer 33 on the basis of the step S25.

A material of the second insulating layer 32 is deposited, and then a lithography process and an etching process for an intermediate dielectric layer are performed, to form the first via Via1 to the first contact portion 13a of the active layer, the fourth via Via4 to the second contact portion 13b, the fifth via Via5 to the third contact portion 23a, and the second via Via2 to the fourth contact portion 23b.
The step S27 includes, as shown in FIG. 16f, forming the second conductive layer 42 on a side of the third insulating layer 33 away from the base substrate 1.

The material of the second conductive layer 42 is a source/drain metal in which the drain electrode of the first transistor T1 is electrically connected to the first contact portion 13a through the first via Via1 extending through the third insulating layer 33. The source electrode of the first transistor T1 and the drain electrode of the second transistor T2 are electrically connected to each other, and are electrically connected to the second contact portion 13b and the third contact portion 23a through the fourth via Via4 and the fifth via Via5, respectively. The source electrode of the second transistor T2 is electrically connected to the fourth contact portion 23b through one second via Via2. The auxiliary component 6 is further used as the source electrode of the second transistor T2. The auxiliary component 6 is connected to the first electric pole 22 through the second via Via3.
The step S28 includes, as shown in FIG. 16g, forming the fourth insulating layer 34 on a side of the second conductive layer 42 away from the third insulating layer 33.

The fourth insulating layer 34 may be a planarization layer 342.

A material of the planarization layer is deposited, and a lithography process for an organic material is then performed to form the first sub-via Via31.
The step S29 includes, as shown in FIG. 16h, forming the second electric pole 23 on a side of the fourth insulating layer 34 away from the third insulating layer 33.

The second electric pole 23 is a common electrode.
The step S210 includes, as shown in FIG. 16i, forming the fifth insulating layer 35 on a side of the second electric pole 23 away from the fourth insulating layer 34.

The fifth insulating layer 35 is a passivation layer.

A material of the passivation layer is deposited, and a lithography process for the passivation layer and an etching process are then performed to form the second sub-via Via32 to the second electrode T22 of the second transistor T2.

The step S211 includes, as shown in FIG. 16j, forming the pixel electrode ITO on a side of the fifth insulating layer 35 away from the second electric pole 23.

The pixel electrode ITO is a slit electrode. The pixel electrode ITO has a connection portion connected to the auxiliary component 6 (i.e., the second electrode T22 of the second transistor T2) through the third via Via3; the auxiliary component 6 is connected to the fourth contact portion 23b through the second via Via2.

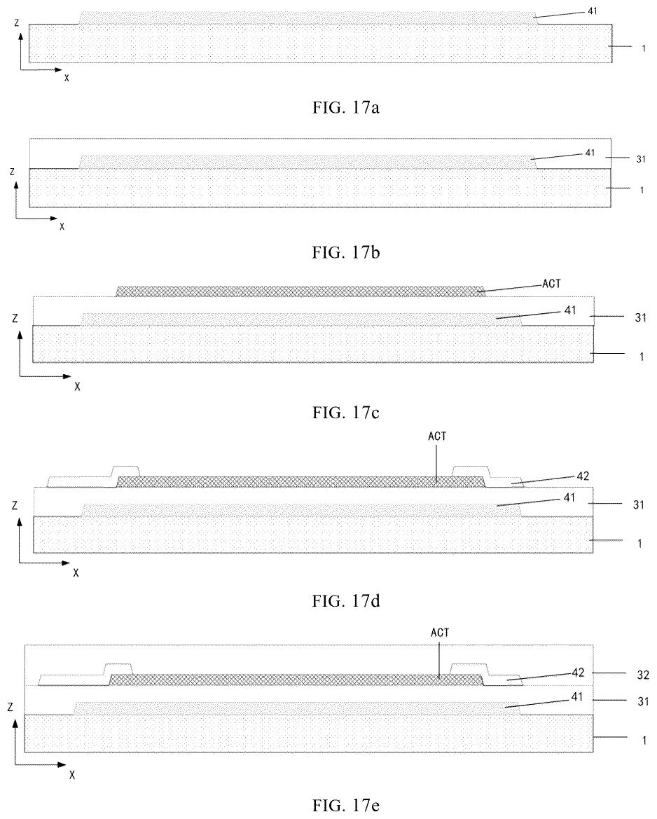

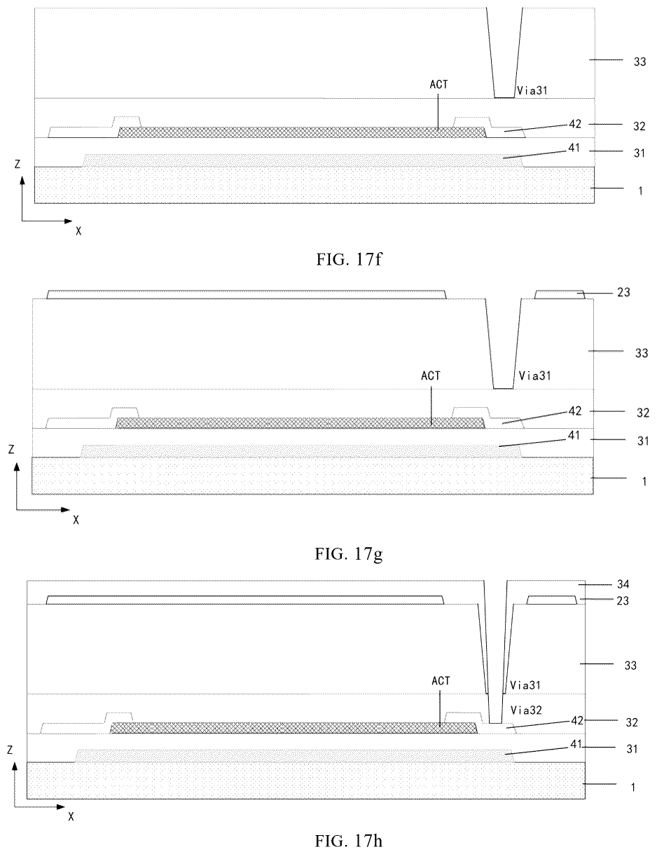

In some embodiments, FIGS. 17a to 17i are schematic diagrams illustrating a process for manufacturing a display substrate shown in FIG. 13b according to an embodiment of the present disclosure. The method specifically includes the following steps S31 to S310:
The step S31 includes, providing the base substrate 1.

In this step, the base substrate 1 is a glass substrate.
The step S32 includes, as shown in FIG. 17a, forming the first conductive layer 41 on the base substrate 1.

The first conductive layer 41 is a composite layer, and includes a buffer layer and a main conductive layer sequentially disposed on the base substrate 1. The buffer layer may be made of a Ti-based alloy material or a Mo-based alloy material, and the main conductive layer may be made of Al or Cu.

The first conductive layer 41 includes the gate lines Gate further used as the gate electrodes of the first transistors T1 and the gate electrodes of the second transistors T2.
The step S33 includes, as shown in FIG. 17b, forming the first insulating layer 31 on a side of the first conductive layer 41 away from the base substrate 1.
The step S34 includes, as shown in FIG. 17c, forming the semiconductor layer ACT on a side of the first insulating layer 31 away from the light shielding layer 50.

Specifically, a material of the semiconductor layer ACT is deposited, the material of the semiconductor layer ACT is selected from oxide materials with a high mobility such as IGZTO, IGO, or the like, and the material of the semiconductor layer ACT is then subjected to conventional annealing and patterning processes.

The semiconductor layer ACT is conductorized by using a mask plate. The conductorization process may be performed by plasma of a gas (including a mixed gas) such as He, Ar, H₂, or NH₃ or the like, so that the first contact portion 13a and the fourth contact portion 23b of the active layer are formed.
The step S35 includes, as shown in FIG. 17d, forming the second conductive layer 42 on a side of the semiconductor layer ACT away from the first insulating layer 31.

The second conductive layer 42 includes the first electrode T11 of each first transistor T1 and the second electrode T22 of each second transistor T2. The first electrode T11 of the first transistor T1 is directly connected to the first contact portion 13a, the second contact portion 13b is further used as the first channel portion 13c of the first transistor T1, and the third contact portion 23a is further used as the second channel portion 23c of the second transistor T2. The second contact portion 13b and the third contact portion 23a are connected together to have a one-piece structure, and the second electrode T22 of the second transistor T2 is directly connected to the fourth contact portion 23b.

In order to prevent the active layer (IGZO) from being damaged too much by the etching liquid, preferably, the second conductive layer 42 is made of a Cu stack and is formed by using a hydrogen peroxide-based etching liquid.
The step S36 includes, as shown in FIG. 17e, forming the second insulating layer 32 on a side of the second conductive layer 42 away from the first insulating layer 31.

The second insulating layer 32 is a channel protection layer.
The step S37 includes, as shown in FIG. 17f, forming the third insulating layer 33 on a side of the second insulating layer 32 away from the second conductive layer 42.

The third insulating layer 33 is a planarization layer.

A material of the planarization layer is deposited, and a lithography process for an organic material is then performed to form the first sub-via Via31.
The step S38 includes, as shown in FIG. 17g, forming the second electric pole 23 on a side of the third insulating layer 33 away from the second insulating layer 32.

The second electric pole 23 is a common electrode.
The step S39 includes, as shown in FIG. 17h, forming the fourth insulating layer 34 on a side of the second electric pole 23 away from the third insulating layer 33.

The fourth insulating layer 34 is a passivation layer.

A material of the passivation layer is deposited, and a lithography process for the passivation layer and an etching process are then performed to form the second sub-via Via32 to the second electrode T22 of the second transistor T2.
The step S310 includes, as shown in FIG. 17i, forming the pixel electrode ITO on a side of the fourth insulating layer 34 away from the second electric pole 23.

The pixel electrode ITO is a slit electrode. The pixel electrode ITO has a connection portion connected to the auxiliary component 6 (i.e., the second electrode T22 of the second transistor T2) through the third via Via3; the auxiliary component 6 is directly connected to the fourth contact portion 2b.

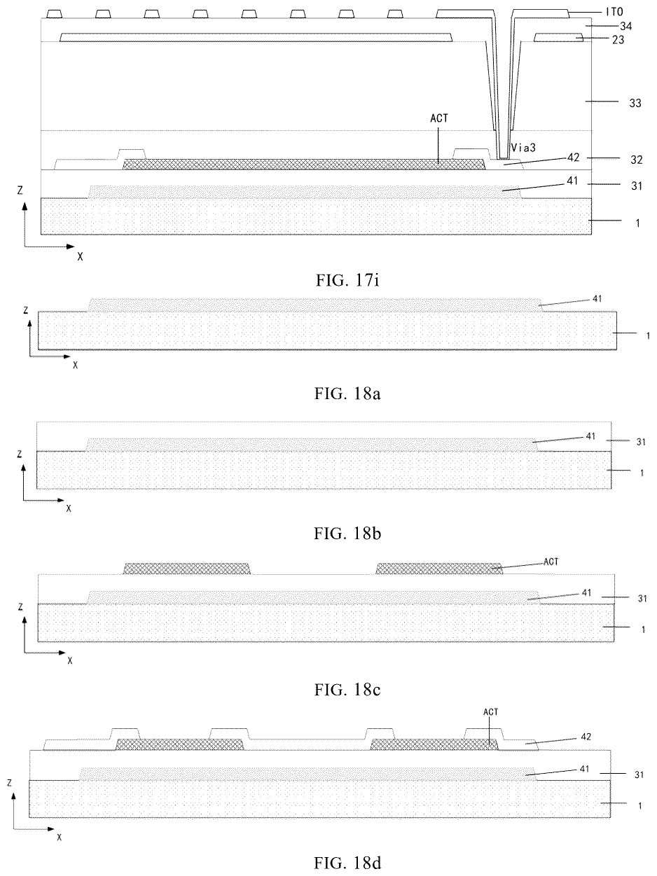

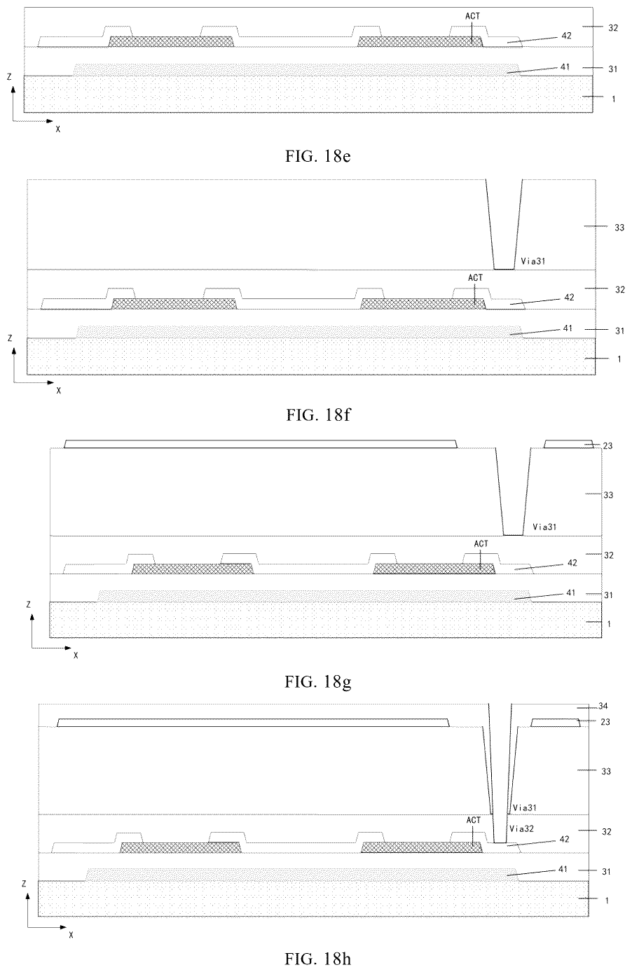

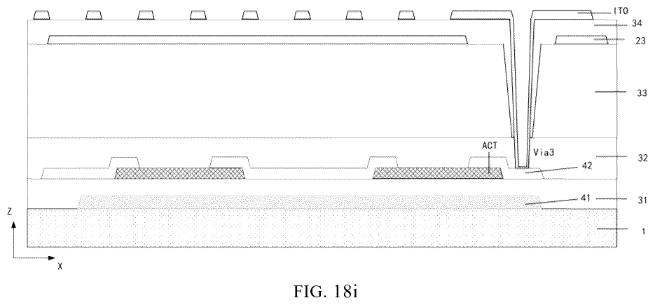

In some embodiments, FIGS. 18a to 18i are schematic diagrams illustrating a process for manufacturing a display substrate shown in FIG. 10 according to an embodiment of the present disclosure. The method specifically includes the following steps S41 to S410:
The step S41 includes, providing the base substrate 1.

In this step, the base substrate 1 is a glass substrate.
The step S42 includes, as shown in FIG. 18a, forming the first conductive layer 41 on the base substrate 1.

The first conductive layer 41 is a composite layer, and includes a buffer layer and a main conductive layer sequentially disposed on the base substrate 1. The buffer layer may be made of a Ti-based alloy material or a Mo-based alloy material, and the main conductive layer may be made of Al or Cu.

The first conductive layer 41 includes the gate lines Gate further used as the gate electrodes of the first transistors T1 and the gate electrodes of the second transistors T2.
The step S43 includes, as shown in FIG. 18b, forming the first insulating layer 31 on a side of the first conductive layer 41 away from the base substrate 1.
The step S44 includes, as shown in FIG. 18c, forming the semiconductor layer ACT on a side of the first insulating layer 31 away from the light shielding layer 50.

Specifically, a material of the semiconductor layer ACT is deposited, the material of the semiconductor layer ACT is selected from oxide materials with a high mobility such as IGZTO, IGO, or the like, and the material of the semiconductor layer ACT is then subjected to conventional annealing and patterning processes.

The semiconductor layer ACT is conductorized by using a mask plate. The conductorization process may be performed by plasma of a gas (including a mixed gas) such as He, Ar, H₂, or NH₃ or the like, so that the first contact portion 13a, the second contact portion 13b, the third contact portion 23a, and the fourth contact portion 23b of the active layer are formed.
The step S45 includes, as shown in FIG. 18d, forming the second conductive layer 42 on a side of the semiconductor layer ACT away from the first insulating layer 31.

The second conductive layer 42 includes the first electrode T11 and the second electrode of each first transistor T1 and the first electrode T21 and the second electrode of each second transistor T2. The second electrode T12 of the first transistor T1 and the first electrode T21 of the second transistor T2 have a one-piece structure. The first electrode T11 of the first transistor T1 is directly connected to the first contact portion 13a, the second electrode T12 of the first transistor T1 is directly connected to the second contact portion 13b, the first electrode T21 of the second transistor T2 is directly connected to the third contact portion 23a, and the second electrode T22 of the second transistor T2 is directly connected to the fourth contact portion 23b.

In order to prevent the active layer (IGZO) from being damaged too much by the etching liquid, preferably, the second conductive layer 42 is made of a Cu stack and is formed by using a hydrogen peroxide-based etching liquid.
The step S46 includes, as shown in FIG. 18e, forming the second insulating layer 32 on a side of the second conductive layer 42 away from the first insulating layer 31.

The second insulating layer 32 is a channel protection layer.
The step S47 includes, as shown in FIG. 18f, forming the third insulating layer 33 on a side of the second insulating layer 32 away from the second conductive layer 42.

The third insulating layer 33 is a planarization layer.

A material of the planarization layer is deposited, and a lithography process for an organic material is then performed to form the first sub-via Via31.
The step S48 includes, as shown in FIG. 18g, forming the second electric pole 23 on a side of the third insulating layer 33 away from the second insulating layer 32.

The second electric pole 23 is a common electrode.
The step S49 includes, as shown in FIG. 18h, forming the fourth insulating layer 34 on a side of the second electric pole 23 away from the third insulating layer 33.

The fourth insulating layer 34 is a passivation layer.

A material of the passivation layer is deposited, and a lithography process for the passivation layer and an etching process are then performed to form the second sub-via Via32 to the second electrode T22 of the second transistor T2.
The step S410 includes, as shown in FIG. 18i, forming the pixel electrode ITO on a side of the fourth insulating layer 34 away from the second electric pole 23.

The pixel electrode ITO is a slit electrode. The pixel electrode ITO has a connection portion connected to the auxiliary component 6 (i.e., the second electrode T22 of the second transistor T2) through the third via Via3; the auxiliary component 6 is directly connected to the fourth contact portion 2b.

It should be understood that the above embodiments are merely exemplary embodiments adopted to explain the principles of the present disclosure, and the present disclosure is not limited thereto. It will be apparent to one of ordinary skill in the art that various changes and modifications may be made therein without departing from the spirit and scope of the present disclosure, and such changes and modifications also fall within the scope of the present disclosure.

1. A display substrate, comprising a base substrate, and gate lines and data lines on the base substrate, wherein the gate lines and the data lines cross with each other to define a plurality of pixel units; the gate lines extend in a first direction, and the data lines extend in a second direction, and the first direction and the second direction intersect with each other; each of the plurality of pixel units comprises a first transistor and a second transistor, an active layer of the first transistor comprises a first contact portion and a second contact portion, an active layer of the second transistor comprises a third contact portion and a fourth contact portion, the first contact portion is electrically connected to a corresponding data line of the plurality of data lines, the second contact portion is electrically connected to the third contact portion, and the fourth contact portion is electrically connected to a first electric pole of the pixel unit; and along the second direction, a maximum distance between the first contact portion and a corresponding gate line of the plurality of gate lines is not less than a maximum distance between the fourth contact portion and the same corresponding gate line.

2. The display substrate of claim 1, wherein a width of the first contact portion is less than a width of the fourth contact portion along the first direction.

3. The display substrate of claim 1, wherein an orthographic projection of the first contact portion on the base substrate overlaps with an orthographic projection of the corresponding data line on the base substrate, the first contact portion comprises a first section and a second section connected to each other, the first section is electrically connected to the corresponding data line, and a width of the first section is greater than a width of the second section along the first direction.

4. The display substrate of claim 3, wherein an orthographic projection of the fourth contact portion on the base substrate partially overlaps with an orthographic projection of the corresponding gate line on the base substrate, the fourth contact portion comprises a third section and a fourth section connected to each other, the fourth section is electrically connected to the first electric pole, and a minimum width of the fourth section is greater than a minimum width of the third section along the second direction.

5. The display substrate of claim 1, wherein the first contact portion is electrically connected to the corresponding data line through a first via, the fourth contact portion is electrically connected to the first electric pole through a second via, and a minimum distance between the first via and the corresponding gate line is greater than a minimum distance between the second via and the same corresponding gate line along the second direction.

6. The display substrate of claim 1, wherein the first contact portion is electrically connected to the corresponding data line through a first via, and the fourth contact portion is electrically connected to the first electric pole through a second via and a third via, a minimum distance between the first via and the corresponding gate line is greater than a minimum distance between the second via and the same corresponding gate line along the second direction, and a minimum distance between the third via and the corresponding gate line is less than a minimum distance between the second via and the same corresponding gate line.

7. The display substrate of claim 6, wherein each of the plurality of pixel units further comprises an auxiliary component, the auxiliary component comprises a fifth section and a sixth section connected to each other, the fifth section is electrically connected to the fourth contact portion through the second via, and the sixth section is electrically connected to the first electric pole through the third via, and
the auxiliary component is arranged in a same layer as the plurality of data lines, and the auxiliary component is arranged between positions where two adjacent data lines are connected to the first contact portions in the first direction.

8. (canceled)

9. The display substrate of claim 1, wherein the first contact portion, the second contact portion, the third contact portion, and the fourth contact portion are in a same layer.

10. The display substrate of claim 1, wherein the active layer of the first transistor and/or the active layer of the second transistor comprises a metal oxide semiconductor material.

11. The display substrate of claim 10, wherein the active layer of the first transistor and the active layer of the second transistor each comprise a plurality of sub-layers arranged in a stack, and a sub-layer further from the base substrate has a lower mobility than a sub-layer closer to the base substrate.

12. The display substrate of claim 1, wherein a gate electrode of the first transistor is on a side of the active layer of the first transistor away from the base substrate, a gate electrode of the second transistor is on a side of the active layer of the second transistor away from the base substrate, and the active layer of the first transistor and the active layer of the second transistor are in a same layer; and
the corresponding data line is further used as a first electrode of the first transistor, the second contact portion is further used as a second electrode of the first transistor, the third contact portion is further used as a first electrode of the second transistor, and the second contact portion and the third contact portion are connected together to have a one-piece structure.

13. The display substrate of claim 12, wherein the first electric pole is a pixel electrode, and an orthographic projection of the second contact portion and the third contact portion connected together to have a one-piece structure on the base substrate partially overlaps with an orthographic projection of the pixel electrode on the base substrate.

14. The display substrate of claim 13, wherein for any two adjacent pixel units of the plurality of pixel units, an orthographic projection of the second contact portion and the third contact portion connected together to have a one-piece structure in one of the two adjacent pixel units on the base substrate partially overlaps with an orthographic projection of the other of the two adjacent pixel units on the base substrate.

15. The display substrate of claim 12, wherein the active layer of the first transistor further comprises a first channel portion between the first contact portion and the second contact portion, the active layer of the second transistor further comprises a second channel portion between the third contact portion and the fourth contact portion, and a shape of an outline of an orthographic projection of a pattern comprising the first channel portion, the second contact portion and the third contact portion connected together to have a one-piece structure, and the second channel portion on the base substrate has a U shape.

16. The display substrate of claim 1, wherein a gate electrode of the first transistor and a gate electrode of the second transistor are in a same layer, the active layer of the first transistor and the active layer of the second transistor are in a same layer, and a first electrode and a second electrode of the first transistor are in a same layer as a first electrode and a second electrode of the second transistor;
the gate electrode of the first transistor is on a side of the active layer away from the base substrate, and the first electrode and the second electrode of the first transistor are on a side of the gate electrode away from the active layer; and
the corresponding data line is further used as the first electrode of the first transistor, the second electrode of the first transistor and the first electrode of the second transistor are connected together to have a one-piece structure, the second electrode of the first transistor is electrically connected to the second contact portion through a fourth via, and the first electrode of the second transistor is electrically connected to the third contact portion through a fifth via.

17. The display substrate of claim 12, wherein the display substrate further comprises a light shielding layer on a side of the plurality of pixel units close to the base substrate;
the active layer of the first transistor further comprises a first channel portion between the first contact portion and the second contact portion, and the active layer of the second transistor further comprises a second channel portion between the third contact portion and the fourth contact portion; and
an orthographic projection of the light shielding layer on the base substrate at least covers an orthographic projection of each of the first channel portion and the second channel portion on the base substrate.

18. The display substrate of claim 17, wherein an edge of an outline of an orthographic projection of the light shielding layer on the base substrate is spaced apart from an edge of an outline of an orthographic projection of the first channel portion on the base substrate by a first distance in the first direction,
the edge of the outline of the orthographic projection of the light shielding layer on the base substrate is spaced apart from an edge of an outline of an orthographic projection of the second channel portion on the base substrate by a second distance in the first direction; and
the first distance and/or the second distance is in a range from 4 μm to 6 μm; and
an edge of an outline of an orthographic projection of the light shielding layer on the base substrate is spaced apart from an edge of an outline of an orthographic projection of the first channel portion on the base substrate by a third distance in the second direction;
the edge of the outline of the orthographic projection of the light shielding layer on the base substrate is spaced apart from an edge of an outline of an orthographic projection of the second channel portion on the base substrate by a fourth distance in the second direction; and
the third distance and/or the fourth distance is in a range from 0 to 4 μm.

19. (canceled)

20. The display substrate of claim 16, wherein pixel units of the plurality of pixel units in a same row are electrically connected to a same gate line, and the corresponding gate line is used as a gate electrode of the first transistor and a gate electrode of the second transistor; and
the display substrate further comprises a gate insulating layer on a side of a gate electrode of the first transistor close to the active layer, wherein a thickness of the gate insulating layer is in a range from 10 mm to 30 nm.

21. (canceled)

22. The display substrate of claim 1, wherein a gate electrode of the first transistor and a gate electrode of the second transistor are in a same layer, the active layer of the first transistor and the active layer of the second transistor are in a same layer, and a first electrode and a second electrode of the first transistor are in a same layer as a first electrode and a second electrode of the second transistor;
the gate electrode of the first transistor is on a side of the active layer close to the base substrate, and the first electrode and the second electrode of the first transistor are on a side of the active layer away from the gate electrode; and
the corresponding data line is further used as the first electrode of the first transistor, the second electrode of the first transistor and the first electrode of the second transistor are connected together to have a one-piece structure, and the second electrode of the first transistor is electrically connected to the second contact portion of the first transistor, and the first electrode of the second transistor is electrically connected to the third contact portion of the second transistor;
pixel units of the plurality of pixel units in a same row are electrically connected to a same gate line, and the corresponding gate line serves as the gate electrode of the first transistor and the gate electrode of the second transistor; and each of the plurality of gate lines is of a composite-layer structure, which comprises a buffer layer and a main conductive layer sequentially arranged on the base substrate; and
the display substrate further comprises a gate insulating layer on a side of the gate electrode of the first transistor close to the active layer, wherein a thickness of the gate insulating layer is in a range from 30 nm to 50 nm.

23-24. (canceled)

25. A display apparatus, comprising the display substrate of claim 1.
